(19) United States
(12) Patent Application Publication
(10) Pub. No.: US 2025/0253686 A1
(43) Pub. Date: Aug. 7, 2025

(54) MULTIPORT USB FAST CHARGERS WITH FAST-CHARGING CONTROLLER CHIPS INCLUDING TRANSISTOR COMBINATIONS ON THREE CHIP BASES

(71) Applicant: ON-BRIGHT ELECTRONICS (SHANGHAI) CO., LTD., Shanghai (CN)

(72) Inventors: GUANGWEN ZHENG, Shanghai (CN); MENGKE SHA, Shanghai (CN); ZHIQIN ZHAO, Shanghai (CN); ZHILIANG CHEN, Shanghai (CN)

(21) Appl. No.: 18/431,339

(22) Filed: Feb. 2, 2024

(30) Foreign Application Priority Data
Jan. 5, 2023 (CN) 202310012633.3

(51) Int. Cl. H02J 7/00; H03K 19/003; H03K 19/0185

(52) U.S. Cl. CPC H02J 7/00309; H03K 19/00315; H03K 19/018557; H02J 2207/30

(57) ABSTRACT

Chip package and method thereof. For example, a chip package of a charging controller chip for a USB charger includes: a high-side transistor including a first drain, a first gate and a first source; a low-side transistor including a second drain, a second gate and a second source, the low-side transistor being connected to the high-side transistor; one or more port transistors corresponding to one or more USB output ports respectively, each port transistor of the one or more port transistors including a third drain, a third gate and a third source; a controller coupled to the high-side transistor, the low-side transistor, and the one or more port transistors; a first chip base; a second chip base electrically insulated from the first chip base; and a third chip base electrically insulated from the first chip base and electrically insulated from the second chip base.

### 1. CROSS-REFERENCES TO RELATED APPLICATIONS

This application claims priority to Chinese Patent Application No. 202310012633.3, filed on Jan. 5, 2023, incorporated by reference herein for all purposes.

### 2. FIELD OF THE DISCLOSURE

Certain embodiments of the present disclosure are directed to circuits. More particularly, some embodiments of the disclosure provide multiport USB fast chargers with fast-charging controller chips including transistor combinations. Merely by way of example, some embodiments of the disclosure have been applied to placing the transistor combinations onto three chip bases when packaging each fast-charging controller chip. But it would be recognized that the disclosure has a much broader range of applicability.

### 3. BACKGROUND OF THE DISCLOSURE

With the increasing battery capacity of electronic devices and the continuous development of fast charging protocols for Universal Serial Bus (USB), the use of USB fast chargers has become more and more widespread. Usually a USB fast charger includes two or more USB output ports to charge two or more loads (e.g., two or more mobile electronic devices) at the same time. The USB fast chargers often generate a large charging current, which can cause the USB fast chargers to overheat. Therefore, there is a need to reduce the risk of overheating in the USB fast chargers.

FIG. 1 is a simplified diagram showing a conventional three-port USB fast charger. The USB fast charger 100 includes an AC-to-DC converter 110, fast-charging controller chips 120 and 130, inductive coils 122 and 132, capacitors 173, 183 and 193, resistors 172, 182 and 192, transistors 174, 184 and 194, and USB output ports 170, 180 and 190. The USB output port 170 is connected to a load (e.g., a mobile electronic device), the USB output port 180 is connected to a load (e.g., a mobile electronic device), and/or the USB output port 190 is connected to a load (e.g., a mobile electronic device). For example, the AC-to-DC converter 110 receives a voltage 109 (e.g., an AC voltage) and generates a voltage 111 (e.g., a DC voltage) based at least in part on the voltage 109. As an example, each output port of the USB output ports 170, 180 and 190 is a USB Type-C output port.

The fast-charging controller chip 120 includes a fast-charging-protocol unit and one or more additional components. In some examples, the one or more additional components of the fast-charging controller chip 120 are parts of a DC-to-DC converter (e.g., a switching regulator unit) that corresponds to the USB output ports 170 and 180, and the DC-to-DC converter also includes the inductive coil 122, the capacitors 173 and 183, and the resistors 172 and 182. The DC-to-DC converter (e.g., a switching regulator unit) that corresponds to the USB output ports 170 and 180 is a buck converter (e.g., a step-down converter), a boost converter (e.g., a step-up converter), or a buck-boost converter. For example, the DC-to-DC converter (e.g., a switching regulator unit) receives the voltage 111 and generates voltages 171 and 181 based at least in part on the voltage 111. As an example, the voltage 171 and the voltage 181 are the same. In certain examples, the voltage 171 is received by the resistor 172 that is connected to the transistor 174, and the voltage 181 is received by the resistor 182 that is connected to the transistor 184. For example, when the transistor 174 is turned on, a voltage 175 is outputted to the USB output port 170. As an example, when the transistor 184 is turned on, a voltage 185 is outputted to the USB output port 180. The capacitor 173, the resistor 172 and the transistor 174 are external to the fast-charging controller chip 120, and the capacitor 183, the resistor 182 and the transistor 184 are also external to the fast-charging controller chip 120.

The fast-charging controller chip 130 includes a fast-charging-protocol unit and one or more additional components. In some examples, the one or more additional components of the fast-charging controller chip 130 are parts of a DC-to-DC converter (e.g., a switching regulator unit) that corresponds to the USB output port 190, and the DC-to-DC converter also includes the inductive coil 132, the capacitor 193, and the resistor 192. The DC-to-DC converter (e.g., a switching regulator unit) that corresponds to the USB output port 190 is a buck converter (e.g., a step-down converter), a boost converter (e.g., a step-up converter), or a buck-boost converter. For example, the DC-to-DC converter (e.g., a switching regulator unit) receives the voltage 111 and generates a voltage 191 based at least in part on the voltage 111. In certain examples, the voltage 191 is received by the resistor 192 that is connected to the transistor 194. For example, when the transistor 194 is turned on, a voltage 195 is outputted to the USB output port 190. The capacitor 193, the resistor 192 and the transistor 194 are external to the fast-charging controller chip 130.

As shown in FIG. 1, the AC-to-DC converter 110 provides the total power of the USB fast charger 100. For example, the fast-charging controller chip 120 communicates with a load (e.g., a mobile electronic device) through the USB output port 170 in order to detect and provide the charging power needed by the load that is connected to the USB output port 170, and/or communicates with a load (e.g., a mobile electronic device) through the USB output port 180 in order to detect and provide the charging power needed by the load that is connected to the USB output port 180. As an example, the fast-charging controller chip 130 communicates with a load (e.g., a mobile electronic device) through the USB output port 190 in order to detect and provide the charging power needed by the load that is connected to the USB output port 190. In some examples, the actual value of the voltage 111 (e.g., a DC voltage) generated by the AC-to-DC converter 110 is larger than or equal to the maximum value of the voltage 175, is larger than or equal to the maximum value of the voltage 185, and is larger than or equal to the maximum value of the voltage 195. For example, the actual value of the voltage 175 is smaller than or equal to the maximum value of the voltage 175. As an example, the actual value of the voltage 185 is smaller than or equal to the maximum value of the voltage 185. For example, the actual value of the voltage 195 is smaller than or equal to the maximum value of the voltage 195.

When the actual value of the voltage 175, the actual value of the voltage 185, and/or the actual value of the voltage 195 is much smaller than the actual value of the actual voltage 111, the large difference between the actual value of the voltage 175 and the actual value of the voltage 111, the large difference between the actual value of the voltage 185 and the actual value of the voltage 111, and/or the large difference between the actual value of the voltage 195 and the actual value of the voltage 111 often causes an increase in the switching loss and thus a rise in temperature of the USB fast charger 100. When the temperature of the USB fast charger 100 reaches a predetermined threshold, the USB fast charger 100 usually enters the over-temperature protection and stops the normal operation. Therefore, to maintain the normal operation, the risk of overheating of the USB fast charger 100 often needs to be reduced.

Hence it is highly desirable to improve the technique for USB fast chargers.

### 4. BRIEF SUMMARY OF THE DISCLOSURE

Certain embodiments of the present disclosure are directed to circuits. More particularly, some embodiments of the disclosure provide multiport USB fast chargers with fast-charging controller chips including transistor combinations. Merely by way of example, some embodiments of the disclosure have been applied to placing the transistor combinations onto three chip bases when packaging each fast-charging controller chip. But it would be recognized that the disclosure has a much broader range of applicability.

According to certain embodiments, a chip package of a charging controller chip for a USB charger includes: a high-side transistor including a first drain, a first gate and a first source; a low-side transistor including a second drain, a second gate and a second source, the low-side transistor being connected to the high-side transistor; one or more port transistors corresponding to one or more USB output ports respectively, each port transistor of the one or more port transistors including a third drain, a third gate and a third source; a controller coupled to the high-side transistor, the low-side transistor, and the one or more port transistors; a first chip base; a second chip base electrically insulated from the first chip base; and a third chip base electrically insulated from the first chip base and electrically insulated from the second chip base; wherein: the one or more port transistors are located on the first chip base; the high-side transistor and the controller are located on the second chip base; and the low-side transistor is located on the third chip base.

According to some embodiments, a chip package of a charging controller chip for a USB charger includes: a high-side transistor including a first drain, a first gate and a first source; a low-side transistor including a second drain, a second gate and a second source, the low-side transistor being connected to the high-side transistor; one or more port transistors corresponding to one or more USB output ports respectively, each port transistor of the one or more port transistors including a third drain, a third gate and a third source; a controller coupled to the high-side transistor, the low-side transistor, and the one or more port transistors; a first chip base; a second chip base electrically insulated from the first chip base; and a third chip base electrically insulated from the first chip base and electrically insulated from the second chip base; wherein: the one or more port transistors are located on the first chip base; the high-side transistor is located on the second chip base; and the low-side transistor and the controller are located on the third chip base.

According to certain embodiments, a chip package of a charging controller chip for a USB charger includes: a high-side transistor including a first drain, a first gate and a first source; a low-side transistor including a second drain, a second gate and a second source, the low-side transistor being connected to the high-side transistor; one or more port transistors corresponding to one or more USB output ports respectively, each port transistor of the one or more port transistors including a third drain, a third gate and a third source; a controller coupled to the high-side transistor, the low-side transistor, and the one or more port transistors; a first chip base; a second chip base electrically insulated from the first chip base; and a third chip base electrically insulated from the first chip base and electrically insulated from the second chip base; wherein: the one or more port transistors and the controller are located on the first chip base; the high-side transistor is located on the second chip base; and the low-side transistor is located on the third chip base.

Depending upon embodiment, one or more benefits may be achieved. These benefits and various additional objects, features and advantages of the present disclosure can be fully appreciated with reference to the detailed description and accompanying drawings that follow.

### 5. BRIEF DESCRIPTION OF THE DRAWINGS

FIG. 1 is a simplified diagram showing a conventional three-port USB fast charger.

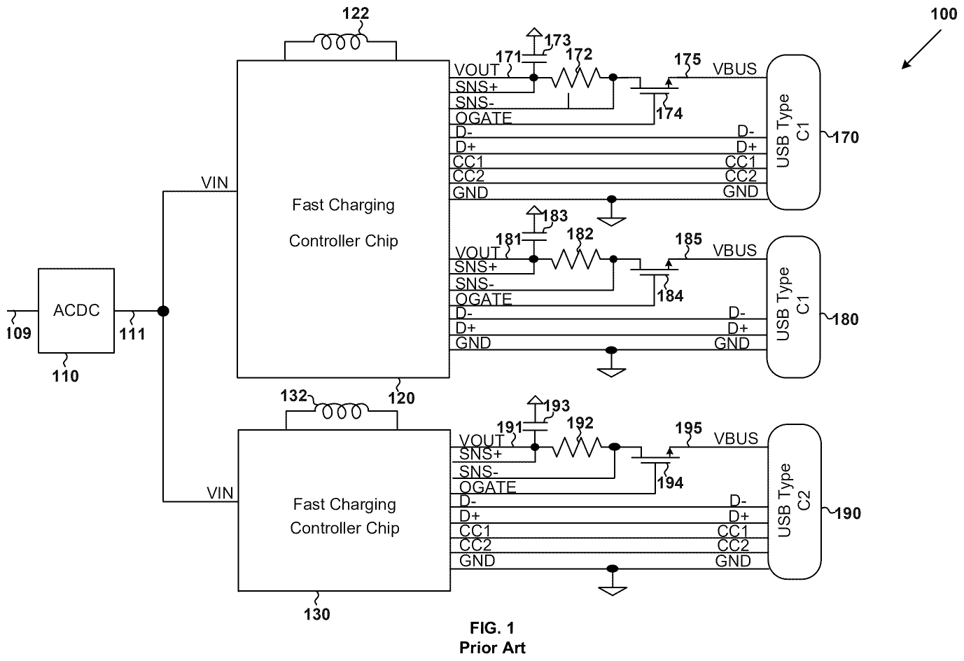

FIG. 2 is a simplified diagram showing a three-port USB fast charger according to certain embodiments.

FIG. 3 is a simplified diagram showing a three-port USB fast charger according to some embodiments of the present disclosure.

FIG. 4 is a simplified diagram showing a transistor combination that is used as one or more transistor combinations of the USB fast charger as shown in FIG. 3 according to certain embodiments of the present disclosure.

FIG. 5 is a simplified diagram showing certain components of a fast-charging controller chip as part of the three-port USB fast charger as shown in FIG. 3 according to certain embodiments of the present disclosure.

FIG. 6A and FIG. 6B are simplified diagrams showing a chip package of the fast-charging controller chip as shown in FIG. 5 as part of the three-port USB fast charger as shown in FIG. 3 according to some embodiments of the present disclosure.

FIG. 7A and FIG. 7B are simplified diagrams showing a chip package of the fast-charging controller chip as shown in FIG. 5 as part of the three-port USB fast charger as shown in FIG. 3 according to certain embodiments of the present disclosure.

FIG. 8A and FIG. 8B are simplified diagrams showing a chip package of the fast-charging controller chip as shown in FIG. 5 as part of the three-port USB fast charger as shown in FIG. 3 according to some embodiments of the present disclosure.

FIG. 9 is a simplified diagram showing certain components of the chip package as shown in FIG. 6A and FIG. 6B as part of the three-port USB fast charger as shown in FIG. 3 according to some embodiments of the present disclosure.

FIG. 10 is a simplified diagram showing certain components of the chip package as shown in FIG. 7A and FIG. 7B as part of the three-port USB fast charger as shown in FIG. 3 according to some embodiments of the present disclosure.

FIG. 11 is a simplified diagram showing certain components of the chip package as shown in FIG. 8A and FIG. 8B as part of the three-port USB fast charger as shown in FIG. 3 according to some embodiments of the present disclosure.

### 6. DETAILED DESCRIPTION OF THE DISCLOSURE

Certain embodiments of the present disclosure are directed to circuits. More particularly, some embodiments of the disclosure provide multiport USB fast chargers with fast-charging controller chips including transistor combinations. Merely by way of example, some embodiments of the disclosure have been applied to placing the transistor combinations onto three chip bases when packaging each fast-charging controller chip. But it would be recognized that the disclosure has a much broader range of applicability.

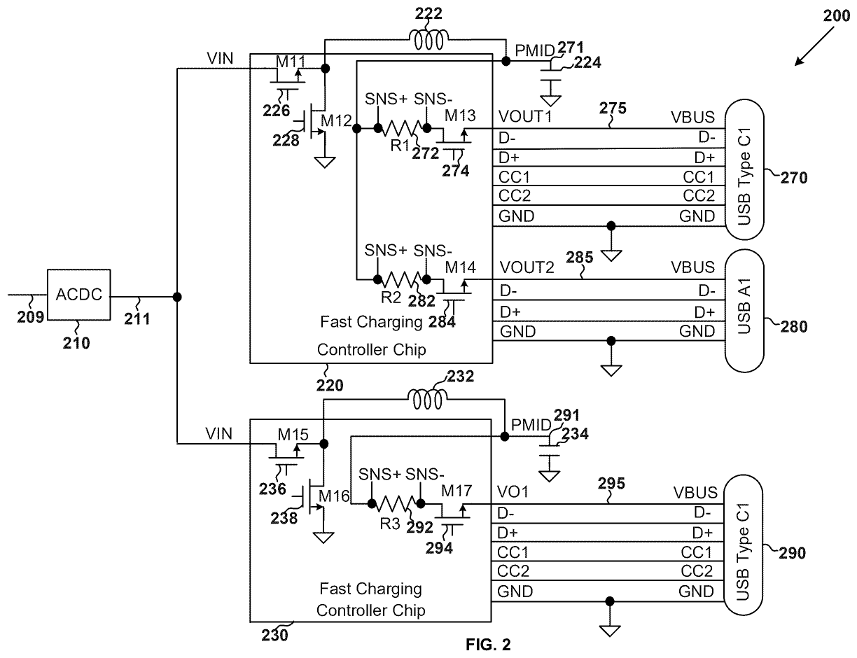

FIG. 2 is a simplified diagram showing a three-port USB fast charger according to certain embodiments. The USB fast charger 200 includes an AC-to-DC converter 210, fast-charging controller chips 220 and 230, inductive coils 222 and 232, capacitors 224 and 234, and USB output ports 270, 280 and 290. For example, the fast-charging controller chip 220 includes a fast-charging-protocol unit, transistors 226 and 228, resistors 272 and 282, and transistors 274 and 284. As an example, the fast-charging controller chip 230 includes a fast-charging-protocol unit, transistors 236 and 238, a resistor 292, and a transistor 294. In some examples, the AC-to-DC converter 210 receives a voltage 209 (e.g., an AC voltage) and generates a voltage 211 (e.g., a DC voltage) based at least in part on the voltage 209. In certain examples, the USB output port 270 is a USB Type-C output port, the USB output port 280 is a USB Type-A output port, and the USB output port 290 is a USB Type-C output port. For example, the USB output port 270 is connected to a load (e.g., a mobile electronic device), the USB output port 280 is connected to a load (e.g., a mobile electronic device), and/or the USB output port 290 is connected to a load (e.g., a mobile electronic device).

In some embodiments, the transistors 226 and 228, the inductive coil 222, and the capacitor 224 are parts of a DC-to-DC converter (e.g., a switching regulator unit) that corresponds to the USB output ports 270 and 280. In certain examples, the DC-to-DC converter (e.g., a switching regulator unit) that corresponds to the USB output ports 270 and 280 is a buck converter (e.g., a step-down converter), a boost converter (e.g., a step-up converter), or a buck-boost converter. For example, the DC-to-DC converter that corresponds to the USB output ports 270 and 280 receives the voltage 211 and generates a voltage 271 based at least in part on the voltage 211. As an example, the voltage 271 is received by the resistor 272 that is connected to the transistor 274, and the voltage 271 is also received by the resistor 282 that is connected to the transistor 284. As shown in FIG. 2, the resistor 272 and the transistor 274 are on the fast-charging controller chip 220, and the resistor 282 and the transistor 284 are also on the fast-charging controller chip 220 according to some embodiments. For example, when the transistor 274 is turned on, a voltage 275 is outputted to the USB output port 270. As an example, when the transistor 284 is turned on, a voltage 285 is outputted to the USB output port 280.

In certain embodiments, the transistors 236 and 238, the inductive coil 232, and the capacitor 234 are parts of a DC-to-DC converter (e.g., a switching regulator unit) that corresponds to the USB output port 290. In some examples, the DC-to-DC converter (e.g., a switching regulator unit) that corresponds to the USB output port 290 is a buck converter (e.g., a step-down converter), a boost converter (e.g., a step-up converter), or a buck-boost converter. For example, the DC-to-DC converter that corresponds to the USB output port 290 receives the voltage 211 and generates a voltage 291 based at least in part on the voltage 211. As an example, the voltage 291 is received by the resistor 292 that is connected to the transistor 294. As shown in FIG. 2, the resistor 292 and the transistor 294 are on the fast-charging controller chip 230 according to certain embodiments. For example, when the transistor 294 is turned on, a voltage 295 is outputted to the USB output port 290.

According to some embodiments, the transistor 226 is a high-side transistor, and the transistor 228 is a low-side transistor for the DC-to-DC converter (e.g., a switching regulator unit) that corresponds to the USB output ports 270 and 280. For example, the transistor 274 is a USB port transistor that corresponds to the USB output port 270, and the transistor 284 is a USB port transistor that corresponds to the USB output port 280. As an example, all of the transistors 226, 228, 274, and 284 are on the fast-charging controller chip 220.

According to certain embodiments, the transistor 236 is a high-side transistor, and the transistor 238 is a low-side transistor for the DC-to-DC converter (e.g., a switching regulator unit) that corresponds to the USB output port 290. For example, the transistor 294 is a USB port transistor that corresponds to the USB output port 290. As an example, all of the transistors 236, 238, and 294 are on the fast-charging controller chip 230.

In some embodiments, the transistor 274 is connected to the resistor 272, the transistor 284 is connected to the resistor 282, and the transistor 294 is connected to the resistor 292. In certain examples, the resistor 272 is used to detect a current that flows through the transistor 274, the resistor 282 is used to detect a current that flows through the transistor 284, and the resistor 292 is used to detect a current that flows through the transistor 294. For example, the resistor 272 includes one resistor terminal (e.g., SNS+) through which a current flows into the resistor 272, and another resistor terminal (e.g., SNS−) through which the current flows out of the resistor 272. As an example, the resistor 282 includes one resistor terminal (e.g., SNS+) through which a current flows into the resistor 282, and another resistor terminal (e.g., SNS−) through which the current flows out of the resistor 282. For example, the resistor 292 includes one resistor terminal (e.g., SNS+) through which a current flows into the resistor 292, and another resistor terminal (e.g., SNS−) through which the current flows out of the resistor 292.

In certain embodiments, when the fast-charging controller chip 220 is encapsulated into a package with multiple pins, the drain of the transistor 226 is connected to one or more pins of the package through one or more electrically conductive connecting lines, and the terminals (e.g., SNS+) of the resistors 272 and 282 are connected to one or more pins of the package through one or more electrically conductive connecting lines. For example, the one or more electrically conductive connecting lines for the transistor 226 generate significant heat when one or more currents flow through these one or more electrically conductive connecting lines, causing overheating of the fast-charging controller chip 220 as part of the USB fast charger 200. As an example, the one or more electrically conductive connecting lines for the resistors 272 and 282 generate significant heat when one or more currents flow through these one or more electrically conductive connecting lines, causing overheating of the fast-charging controller chip 220 as part of the USB fast charger 200.

In some embodiments, when the fast-charging controller chip 230 is encapsulated into a package with multiple pins, the drain of the transistor 236 is connected to one or more pins of the package through one or more electrically conductive connecting lines, and the terminal (e.g., SNS+) of the resistor 292 is connected to one or more pins of the package through one or more electrically conductive connecting lines. For example, the one or more electrically conductive connecting lines for the transistor 236 generate significant heat when one or more currents flow through these one or more electrically conductive connecting lines, causing overheating of the fast-charging controller chip 230 as part of the USB fast charger 200. As an example, the one or more electrically conductive connecting lines for the resistors 292 generate significant heat when one or more currents flow through these one or more electrically conductive connecting lines, causing overheating of the fast-charging controller chip 230 as part of the USB fast charger 200.

As mentioned above and further emphasized here, FIG. 2 is merely an example, which should not unduly limit the scope of the claims. One of ordinary skill in the art would recognize many variations, alternatives, and modifications. For example, each transistor of the transistors 226, 228, 236 and 238 is connected to a resistor, which is used to detect a current that flows through the connected transistor. As an example, one or more resistors (e.g., the resistor 272, the resistor 282, and/or the resistor 292) that are connected to the transistor 274, the transistor 284, the transistor 294, the transistor 226, the transistor 228, the transistor 236, and/or the transistor 238 respectively each are large in size in order to achieve a large resistance value, so the one or more resistors also make the fast-charging controller chip 220 and/or the fast-charging controller chip 230 become larger in size.

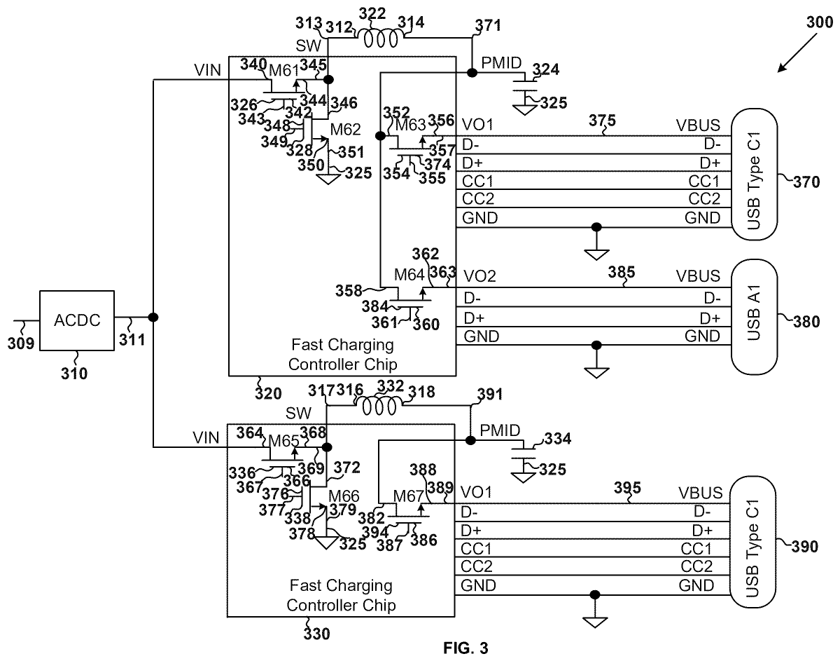

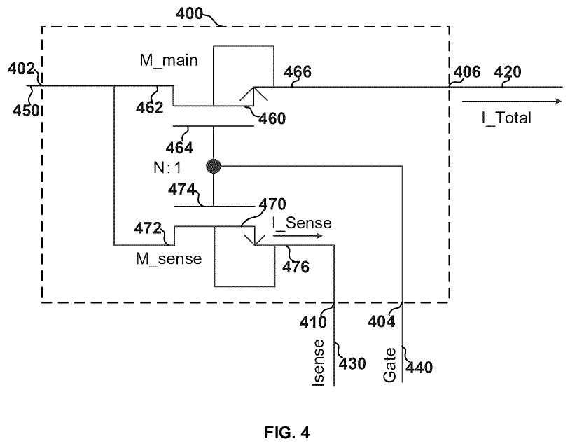

FIG. 3 is a simplified diagram showing a three-port USB fast charger according to some embodiments of the present disclosure. This diagram is merely an example, which should not unduly limit the scope of the claims. One of ordinary skill in the art would recognize many variations, alternatives, and modifications. The USB fast charger 300 includes an AC-to-DC converter 310, fast-charging controller chips 320 and 330, inductive coils 322 and 332, capacitors 324 and 334, and USB output ports 370, 380 and 390. For example, the USB output port 370 is connected to a load (e.g., a mobile electronic device), the USB output port 380 is connected to a load (e.g., a mobile electronic device), and/or the USB output port 390 is connected to a load (e.g., a mobile electronic device). As an example, the USB output port 370 is a USB Type-C output port, the USB output port 380 is a USB Type-A output port, and the USB output port 390 is a USB Type-C output port. In certain examples, the fast-charging controller chip 320 includes a fast-charging-protocol unit and transistor combinations 326, 328, 374, and 384. For example, each transistor combination of the transistor combinations 326, 328, 374, and 384 is implemented according to FIG. 4. In some examples, the fast-charging controller chip 330 includes a fast-charging-protocol unit and transistor combinations 336, 338, and 394. As an example, each transistor combination of the transistor combinations 336, 338, and 394 is implemented according to FIG. 4. Although the above has been shown using a selected group of components for the USB fast charger, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

As shown in FIG. 3, the AC-to-DC converter 310 receives a voltage 309 (e.g., an AC voltage) and generates a voltage 311 (e.g., a DC voltage) based at least in part on the voltage 309 according to certain embodiments. In some embodiments, the transistor combinations 326 and 328, the inductive coil 322, and the capacitor 324 are parts of a DC-to-DC converter (e.g., a switching regulator unit) that corresponds to the USB output ports 370 and 380. In certain examples, the DC-to-DC converter (e.g., a switching regulator unit) that corresponds to the USB output ports 370 and 380 is a buck converter (e.g., a step-down converter), a boost converter (e.g., a step-up converter), or a buck-boost converter. For example, the DC-to-DC converter that corresponds to the USB output ports 370 and 380 receives the voltage 311 (e.g., an input voltage) and generates a voltage 371 (e.g., a converter voltage) based at least in part on the voltage 311. As an example, one terminal of the capacitor 324 is biased to the voltage 371, and another terminal of the capacitor 324 is biased to a ground voltage 325. For example, the voltage 371 is received by the transistor combination 374, and the voltage 371 is also received by the transistor combination 384. In some examples, the transistor combination 374 is on the fast-charging controller chip 320, and the transistor combination 384 is also on the fast-charging controller chip 320.

In certain embodiments, the transistor combinations 336 and 338, the inductive coil 332, and the capacitor 334 are parts of a DC-to-DC converter (e.g., a switching regulator unit) that corresponds to the USB output port 390. In some examples, the DC-to-DC converter (e.g., a switching regulator unit) that corresponds to the USB output port 390 is a buck converter (e.g., a step-down converter), a boost converter (e.g., a step-up converter), or a buck-boost converter. For example, the DC-to-DC converter that corresponds to the USB output port 390 receives the voltage 311 (e.g., an input voltage) and generates a voltage 391 (e.g., a converter voltage) based at least in part on the voltage 311. As an example, one terminal of the capacitor 334 is biased to the voltage 391, and another terminal of the capacitor 334 is biased to the ground voltage 325. For example, the voltage 391 is received by the transistor combination 394. In certain examples, the transistor combination 394 is on the fast-charging controller chip 330.

According to some embodiments, the transistor combination 326 is a high-side transistor combination, and the transistor 328 is a low-side transistor combination for the DC-to-DC converter (e.g., a switching regulator unit) that corresponds to the USB output ports 370 and 380. For example, the transistor combination 374 is a USB port transistor combination that corresponds to the USB output port 370, and the transistor combination 384 is a USB port transistor combination that corresponds to the USB output port 380. As an example, all of the transistor combinations 326, 328, 374, and 384 are on the fast-charging controller chip 320.

According to certain embodiments, the transistor combination 336 is a high-side transistor combination, and the transistor combination 338 is a low-side transistor combination for the DC-to-DC converter (e.g., a switching regulator unit) that corresponds to the USB output port 390. For example, the transistor combination 394 is a USB port transistor combination that corresponds to the USB output port 390. As an example, all of the transistor combinations 336, 338, and 394 are on the fast-charging controller chip 330.

In some embodiments, the transistor combination 326 includes terminals 340, 342 and 344, the transistor combination 328 includes terminals 346, 348 and 350, the transistor combination 374 includes terminals 352, 354 and 356, the transistor combination 384 includes terminals 358, 360 and 362, the transistor combination 336 includes terminals 364, 366 and 368, the transistor combination 338 includes terminals 372, 376 and 378, and the transistor combination 394 includes terminals 382, 386 and 388. In certain embodiments, the inductive coil 322 includes terminals 312 and 314, and the inductive coil 332 includes terminals 316 and 318.

According to certain embodiments, the transistor combinations 326, 328, 374 and 384 are on the fast-charging controller chip 320. For example, the terminal 340 of the transistor combination 326 receives the voltage 311, the terminal 342 of the transistor combination 326 receives a voltage 343, and the terminal 344 of the transistor combination 326 is biased to a voltage 313 and directly connected to the terminal 312 of the inductive coil 322. As an example, the terminal 346 of the transistor combination 328 is biased to the voltage 313 and directly connected to the terminal 312 of the inductive coil 322, the terminal 348 of the transistor combination 328 receives a voltage 349, and the terminal 350 of the transistor combination 328 is biased to the ground voltage 325. For example, the terminal 352 of the transistor combination 374 is directly connected to the terminal 314 of the inductive coil 322, and the terminal 354 of the transistor combination 374 receives a voltage 355. As an example, the terminal 358 of the transistor combination 384 is directly connected to the terminal 314 of the inductive coil 322, and the terminal 360 of the transistor combination 384 receives a voltage 361. In certain examples, when the transistor combination 326 is turned on, the terminal 344 outputs a current 345. In some examples, when the transistor combination 328 is turned on, the terminal 350 outputs a current 351. In certain examples, when the transistor combination 374 is turned on, the terminal 356 outputs a current 357 and a voltage 375 to the USB output port 370. In some examples, when the transistor combination 384 is turned on, the terminal 362 outputs a current 363 and a voltage 385 to the USB output port 380.

According to some embodiments, the transistor combinations 336, 338, and 386 are on the fast-charging controller chip 330. For example, the terminal 364 of the transistor combination 336 receives the voltage 311, the terminal 366 of the transistor combination 336 receives a voltage 367, and the terminal 368 of the transistor combination 336 is biased to a voltage 317 and directly connected to the terminal 316 of the inductive coil 332. As an example, the terminal 372 of the transistor combination 338 is biased to the voltage 317 and directly connected to the terminal 316 of the inductive coil 332, the terminal 376 of the transistor combination 338 receives a voltage 377, and the terminal 378 of the transistor combination 338 is biased to the ground voltage 325. For example, the terminal 382 of the transistor combination 394 is directly connected to the terminal 318 of the inductive coil 332, and the terminal 386 of the transistor combination 394 receives a voltage 387. In certain examples, when the transistor combination 336 is turned on, the terminal 368 outputs a current 369. In some examples, when the transistor combination 338 is turned on, the terminal 378 outputs a current 379. In certain examples, when the transistor combination 394 is turned on, the terminal 388 outputs a current 389 and a voltage 395 to the USB output port 390.

As mentioned above and further emphasized here, FIG. 3 is merely an example, which should not unduly limit the scope of the claims. One of ordinary skill in the art would recognize many variations, alternatives, and modifications. In some embodiments, the USB fast charger 300 includes less than three USB output ports or more than three USB output ports. For example, among the USB output ports 370, 380 and 390, one or more USB output ports are removed from the USB fast charger 300. As an example, one or more USB output ports are added to the USB fast charger 300. For example, one or more USB output ports among the USB output ports 370, 380 and 390 are removed from the USB fast charger 300, and/or one or more additional USB output ports are added to the USB fast charger 300. In certain embodiments, the USB fast charger 300 includes less than two or more than two fast-charging controller chips. For example, among the fast-charging controller chips 320 and 330, one fast-charging controller chip is removed from the USB fast charger 300. As an example, one or more fast-charging controller chips are added to the USB fast charger 300. For example, one or more fast-charging controller chips among the fast-charging controller chips 320 and 330 are removed from the USB fast charger 300, and/or one or more additional fast-charging controller chips are added to the USB fast charger 300. In some embodiments, the fast-charging controller chip 320 is modified to support only one USB output port or support more than two USB output ports. In certain embodiments, the fast-charging controller chip 330 is modified to support two or more USB output ports.

FIG. 4 is a simplified diagram showing a transistor combination 400 that is used as the transistor combination 326, the transistor combination 328, the transistor combination 374, the transistor combination 384, the transistor combination 336, the transistor combination 338, and/or the transistor combination 394 of the USB fast charger 300 as shown in FIG. 3 according to certain embodiments of the present disclosure. This diagram is merely an example, which should not unduly limit the scope of the claims. One of ordinary skill in the art would recognize many variations, alternatives, and modifications. The transistor combination 400 includes a transistor 460 and a transistor 470. Additionally, the transistor combination 400 includes terminals 402, 404, 406, and 410. Although the above has been shown using a selected group of components for the transistor combination, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

In certain embodiments, the transistor 460 (e.g., a field-effect transistor) includes a drain 462, a gate 464 and a source 466, and the transistor 470 (e.g., a field-effect transistor) includes a drain 472, a gate 474 and a source 476. For example, the transistor 460 is a MOSFET. As an example, the transistor 470 is a MOSFET. In some examples, the drain 462 of the transistor 460 and the drain 472 of the transistor 470 are connected to the terminal 402, and the gate 464 of the transistor 460 and the gate 474 of the transistor 470 are connected to the terminal 404. For example, the drain 462 of the transistor 460 and the drain 472 of the transistor 470 are biased to a voltage 450. In certain examples, the source 466 of the transistor 460 is connected to the terminal 406, and the source 476 of the transistor 470 is connected to the terminal 410.

In some embodiments, both of the gate 464 of the transistor 460 and the gate 474 of the transistor 470 receive a voltage 440 through the terminal 404. For example, the voltage 440 is used to turn on and/or turn off the transistor 460 and is used to turn on and/or turn off the transistor 470. In certain examples, when the transistor 460 is turned on, the source 466 of the transistor 460 outputs a current 420 through the terminal 406. In some examples, when the transistor 470 is turned on, the source 476 of the transistor 470 outputs a current 430 through the terminal 410. For example, if both of the transistors 460 and 470 are tuned on, the transistor combination 400 is turned on. As an example, if both of the transistors 460 and 470 are turned off, the transistor combination 400 is turned off.

According to certain embodiments, the transistor 470 is used to sample the current that flows from the drain 462 of the transistor 460 to the source 466 of the transistor 460 when the transistor 460 is turned on. For example, when the transistor 460 is turned on, the current 420 is equal to the current that flows from the drain 462 to the source 466 of the transistor 460, and when the transistor 470 is turned on, the current 430 is equal to the current that flows from the drain 472 to the source 476 of the transistor 470.

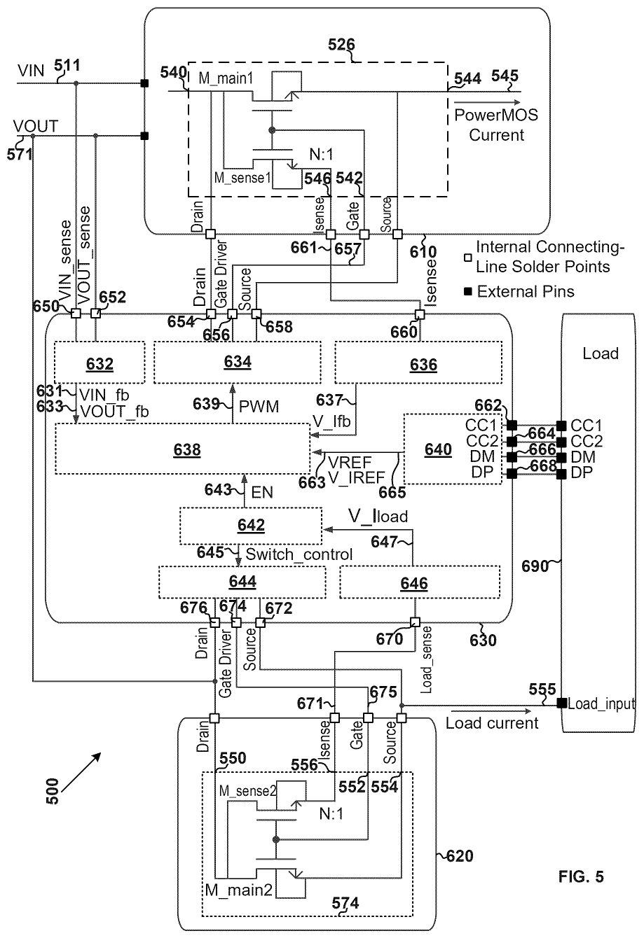

As an example, the current that flows from the drain 472 of the transistor 470 to the source 476 of the transistor 470 is determined as follows:

$${I}_{470} = \frac{1}{N} \times {I}_{460} \qquad ( Equation 1 )$$

where I₄₇₀ represents the current that flows from the drain 472 of the transistor 470 to the source 476 of the transistor 470, and I₄₆₀ represents the current that flows from the drain 462 of the transistor 460 to the source 466 of the transistor 460. N is a predetermined constant (e.g., 1000). In some examples, N is equal to 1000, so if the current (e.g., I₄₆₀) that flows from the drain 462 to the source 466 of the transistor 460 is equal to 3 A, the current (e.g., I₄₇₀) that flows from the drain 472 to the source 476 of the transistor 470 is equal to 3 mA. In certain examples, by detecting the current (e.g., I₄₇₀) that flows from the drain 472 to the source 476 of the transistor 470, the current (e.g., I₄₆₀) that flows from the drain 462 to the source 466 of the transistor 460 is determined as follows:

$${I}_{460} = N \times {I}_{470} \qquad ( Equation 2 )$$

where I₄₆₀ represents the current that flows from the drain 462 of the transistor 460 to the source 466 of the transistor 460, and I₄₇₀ represents the current that flows from the drain 472 of the transistor 470 to the source 476 of the transistor 470. N is a predetermined constant (e.g., 1000). For example, the transistor 470 is used as a sensing transistor, and the transistor 460 is used a main transistor. As an example, a controller (e.g., a controller 630 as shown in FIG. 5) uses the detected current (e.g., I₄₇₀) that flows from the drain 472 to the source 476 of the transistor 470 to determine the current (e.g., I₄₆₀) that flows from the drain 462 to the source 466 of the transistor 460, and turns on and/or turns off the transistors 460 and 470 based at least in part on the current (e.g., I₄₆₀) that flows from the drain 462 to the source 466 of the transistor 460.

According to certain embodiments, the transistor combination 400 is used as the transistor combination 326, the transistor combination 328, the transistor combination 374, and/or the transistor combination 384 of the fast-charging controller chip 320. In some examples, the transistor combination 326 is the transistor combination 400, wherein the transistor 460 is used as a high-side main transistor, and the transistor 470 is used as a high-side sensing transistor. For example, the terminal 340 of the transistor combination 326 is the terminal 402 of the transistor combination 400, the terminal 342 of the transistor combination 326 is the terminal 404 of the transistor combination 400, and the terminal 344 of the transistor combination 326 is the terminal 406 of the transistor combination 400. As an example, the voltage 343 is the voltage 440, the current 345 is the current 420, and the voltage 311 is the voltage 450. In certain examples, the transistor combination 328 is the transistor combination 400, wherein the transistor 460 is used as a low-side main transistor, and the transistor 470 is used as a low-side sensing transistor. For example, the terminal 346 of the transistor combination 328 is the terminal 402 of the transistor combination 400, the terminal 348 of the transistor combination 328 is the terminal 404 of the transistor combination 400, and the terminal 350 of the transistor combination 328 is the terminal 406 of the transistor combination 400. As an example, the voltage 349 is the voltage 440, the current 351 is the current 420, and the voltage 313 is the voltage 450. In some examples, the transistor combination 374 is the transistor combination 400, wherein the transistor 460 is used as a port main transistor, and the transistor 470 is used as a port sensing transistor. For example, the terminal 352 of the transistor combination 374 is the terminal 402 of the transistor combination 400, the terminal 354 of the transistor combination 374 is the terminal 404 of the transistor combination 400, and the terminal 356 of the transistor combination 374 is the terminal 406 of the transistor combination 400. As an example, the voltage 355 is the voltage 440, the current 356 is the current 420, and the voltage 371 is the voltage 450. In certain examples, the transistor combination 384 is the transistor combination 400, wherein the transistor 460 is used as a port main transistor, and the transistor 470 is used as a port sensing transistor. For example, the terminal 358 of the transistor combination 384 is the terminal 402 of the transistor combination 400, the terminal 360 of the transistor combination 384 is the terminal 404 of the transistor combination 400, and the terminal 362 of the transistor combination 384 is the terminal 406 of the transistor combination 400. As an example, the voltage 361 is the voltage 440, the current 363 is the current 420, and the voltage 371 is the voltage 450.

According to some embodiments, the transistor combination 400 is used as the transistor combination 336, the transistor combination 338, and/or the transistor combination 394 of the fast-charging controller chip 330. In certain examples, the transistor combination 336 is the transistor combination 400, wherein the transistor 460 is used as a high-side main transistor, and the transistor 470 is used as a high-side sensing transistor. For example, the terminal 364 of the transistor combination 336 is the terminal 402 of the transistor combination 400, the terminal 366 of the transistor combination 336 is the terminal 404 of the transistor combination 400, and the terminal 368 of the transistor combination 336 is the terminal 406 of the transistor combination 400. As an example, the voltage 367 is the voltage 440, the current 369 is the current 420, and the voltage 311 is the voltage 450. In some examples, the transistor combination 338 is the transistor combination 400, wherein the transistor 460 is used as a low-side main transistor, and the transistor 470 is used as a low-side sensing transistor. For example, the terminal 372 of the transistor combination 338 is the terminal 402 of the transistor combination 400, the terminal 376 of the transistor combination 338 is the terminal 404 of the transistor combination 400, and the terminal 378 of the transistor combination 338 is the terminal 406 of the transistor combination 400. As an example, the voltage 377 is the voltage 440, the current 379 is the current 420, and the voltage 317 is the voltage 450. In certain examples, the transistor combination 394 is the transistor combination 400, wherein the transistor 460 is used as a port main transistor, and the transistor 470 is used as a port sensing transistor. For example, the terminal 382 of the transistor combination 394 is the terminal 402 of the transistor combination 400, the terminal 386 of the transistor combination 394 is the terminal 404 of the transistor combination 400, and the terminal 388 of the transistor combination 394 is the terminal 406 of the transistor combination 400. As an example, the voltage 387 is the voltage 440, the current 389 is the current 420, and the voltage 391 is the voltage 450.

FIG. 5 is a simplified diagram showing certain components of a fast-charging controller chip as part of the three-port USB fast charger 300 as shown in FIG. 3 according to certain embodiments of the present disclosure. This diagram is merely an example, which should not unduly limit the scope of the claims. One of ordinary skill in the art would recognize many variations, alternatives, and modifications. The fast-charging controller chip 500 includes a transistor-combination module 610 for a DC-to-DC converter, a transistor-combination module 620 for one or more USB output ports, and a controller 630. In some examples, the fast-charging controller chip 500 is the fast-charging controller chip 320. For example, the transistor-combination module 610 for a DC-to-DC converter includes the transistor combinations 326 and 328. As an example, the transistor-combination module 620 for one or more USB output ports includes the transistor combinations 374 and 384. In certain examples, the fast-charging controller chip 500 is the fast-charging controller chip 330. For example, the transistor-combination module 610 for a DC-to-DC converter includes the transistor combinations 336 and 338. As an example, the transistor-combination module 620 for one or more USB output ports includes the transistor combination 394. Although the above has been shown using a selected group of components for the fast-charging controller chip, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

In some embodiments, the transistor-combination module 610 for a DC-to-DC converter includes one or more transistor combinations 526, wherein each transistor combination 526 includes terminals 540, 542, 544, and 546. For example, the one or more transistor combinations 526 include one or more high-side transistor combinations and one or more low-side transistor combinations. As an example, the one or more high-side transistor combinations include the high-side transistor combination 326, and the one or more low-side transistor combinations include the low-side transistor combination 328. For example, the one or more high-side transistor combinations include the high-side transistor combination 336, and the one or more low-side transistor combinations include the low-side transistor combination 338. In certain examples, the transistor combination 526 is implemented as the transistor combination 400 as shown in FIG. 4. For example, the terminal 540 is the terminal 402, the terminal 542 is the terminal 404, the terminal 544 is the terminal 406, and the terminal 546 is the terminal 410. As an example, a current 545 is the current 420, a current 661 is the current 430, and a voltage 657 is the voltage 440. In some examples, the one or more transistor combinations 526 include the high-side transistor combination 326 and the low-side transistor combination 328. For example, each transistor combination of the transistor combinations 326 and 328 is a transistor combination 526. In certain examples, the one or more transistor combinations 526 include the high-side transistor combination 336 and the low-side transistor combination 338. As an example, each transistor combination of the transistor combinations 336 and 338 is a transistor combination 526.

In certain embodiments, the transistor-combination module 620 for one or more USB output ports includes one or more transistor combinations 574, wherein each transistor combination 574 includes terminals 550, 552, 554, and 556. In some examples, the transistor combination 574 is implemented as the transistor combination 400 as shown in FIG. 4. For example, the terminal 550 is the terminal 402, the terminal 552 is the terminal 404, the terminal 554 is the terminal 406, and the terminal 556 is the terminal 410. As an example, a current 555 is the current 420, a current 671 is the current 430, and a voltage 675 is the voltage 440. In certain examples, the one or more transistor combinations 574 include the transistor combinations 374 and 384. For example, each transistor combination of the transistor combinations 374 and 384 is a transistor combination 574. In some examples, the one or more transistor combinations 574 include the transistor combination 394. As an example, the transistor combination 394 is a transistor combination 574.

According to some embodiments, the controller 630 is connected to the transistor-combination module 610 for a DC-to-DC converter and the transistor-combination module 620 for one or more USB output ports. In certain examples, the controller 630 is coupled to the main transistor (e.g., the transistor 460) and the sensing transistor (e.g., the transistor 470) of each transistor combination of the transistor combinations (e.g., the transistor combination 326, the transistor combination 328, the transistor combination 336 and/or the transistor combination 338) as parts of the transistor-combination module 610 for a DC-to-DC converter. In some examples, the controller 630 is coupled to the main transistor (e.g., the transistor 460) and the sensing transistor (e.g., the transistor 470) of each transistor combination of the transistor combinations (e.g., the transistor combination 354, the transistor combination 384, and/or the transistor combination 394) as parts of the transistor-combination module 620 for one or more USB output ports. For example, the controller 630 includes an input-voltage and output-voltage detector 632 for the DC-to-DC converter, a gate driver 634 for the one or more transistor combinations 526, a current detector 636 for the one or more transistor combinations 526, a loop control circuit 638 for the DC-to-DC converter, a fast-charging-protocol communication circuit 640, a logic and protection circuit 642, a gate driver 644 for the one or more transistor combinations 574, and a current detector 646 for the one or more transistor combinations 574.

In certain embodiments, the input-voltage and output-voltage detector 632 for the DC-to-DC converter is configured to detect the input voltage and the output voltage of the DC-to-DC converter. For example, the input-voltage and output-voltage detector 632 for the DC-to-DC converter receives a voltage 511 (e.g., the voltage 311) through a terminal 650 (e.g., VIN_sense) and converts the received voltage 511 (e.g., the voltage 311) to a voltage 631 (e.g., VIN_fb) with a voltage divider. As an example, the input-voltage and output-voltage detector 632 for the DC-to-DC converter receives a voltage 571 (e.g., the voltage 371 and/or the voltage 391) through a terminal 652 (e.g., VOUT_sense) and converts the received voltage 571 (e.g., the voltage 371 and/or the voltage 391) to a voltage 633 (e.g., VOUT_fb) with a voltage divider. In some examples, the input-voltage and output-voltage detector 632 for the DC-to-DC converter outputs the voltage 631 (e.g., VIN_fb) and the voltage 633 (e.g., VOUT_fb) to the loop control circuit 638 for the DC-to-DC converter.

In some embodiments, the current detector 636 for the one or more transistor combinations 526 receives the current 661 (e.g., Iₛₑₙₛₑ) from the terminal 546 through a terminal 660 and converts the received current 661 (e.g., Iₛₑₙₛₑ) to a voltage 637 (e.g., V_Ifb) with a current sensing resistor. For example, the voltage 637 (e.g., V_Ifb) is directly proportional to the current 661 (e.g., Iₛₑₙₛₑ). As an example, the current detector 636 for the one or more transistor combinations 526 outputs the voltage 637 (e.g., V_Ifb) to the loop control circuit 638 for the DC-to-DC converter.

According to certain embodiments, the fast-charging-protocol communication circuit 640 communicates with a load 690 (e.g., a mobile electronic device) through a terminal 662 (e.g., CC1), a terminal 664 (e.g., CC2), a terminal 666 (e.g., DM), and a terminal 668 (e.g., DP). In some examples, the fast-charging-protocol communication circuit 640 obtains the magnitude of the charging voltage and/or the magnitude of the charging current that are needed by the load 690. For example, the fast-charging-protocol communication circuit 640 converts the magnitude of the charging voltage needed by the load 690 to a reference voltage 663 (e.g., VREF). As an example, the fast-charging-protocol communication circuit 640 converts the magnitude of the charging current needed by the load 690 to a reference voltage 665 (e.g., V_IREF). In certain examples, the fast-charging-protocol communication circuit 640 outputs the reference voltage 663 (e.g., VREF) and the reference voltage 665 (e.g., V_IREF) to the loop control circuit 638 for the DC-to-DC converter.

According to some embodiments, the current detector 646 for the one or more transistor combinations 574 receives the current 671 (e.g., Iₛₑₙₛₑ) from the terminal 556 through a terminal 670 and converts the received current 671 (e.g., Iₛₑₙₛₑ) to a voltage 647 (e.g., V_Iload) with a current sensing resistor. For example, the voltage 647 (e.g., V_Iload) is directly proportional to the current 671 (e.g., Iₛₑₙₛₑ). As an example, the current detector 646 for the one or more transistor combinations 574 outputs the voltage 647 (e.g., V_Iload) to the logic and protection circuit 642.

In certain embodiments, the logic and protection circuit 642 receives the voltage 647 (e.g., V_Iload). For example, the voltage 647 (e.g., V_Iload) is directly proportional to the current 555. As an example, the current 555 is received by the load 690. In some examples, the logic and protection circuit 642 generates a signal 643 (e.g., EN) based at least in part on the voltage 647 (e.g., V_Iload). For example, if the logic and protection circuit 642 determines that the overheating has occurred and the over-temperature protection needs to be activated, the logic and protection circuit 642 generates the signal 643 (e.g., EN) at a logic low level. As an example, the logic and protection circuit 642 outputs the signal 643 (e.g., EN) to the loop control circuit 638 for the DC-to-DC converter. In certain examples, the logic and protection circuit 642 generates a signal 645 (e.g., Switch_control) based at least in part on the voltage 647 (e.g., V_Iload). For example, if the logic and protection circuit 642 determines that the overheating has occurred and the over-temperature protection needs to be activated, the logic and protection circuit 642 generates the signal 645 (e.g., Switch_control) at a logic low level. As an example, the logic and protection circuit 642 outputs the signal 645 (e.g., Switch_control) to the gate driver 644 for the one or more transistor combinations 574.

In some embodiments, the loop control circuit 638 for the DC-to-DC converter receives the voltage 631 (e.g., VIN_fb), the voltage 633 (e.g., VOUT_fb), the voltage 637 (e.g., V_Ifb), the reference voltage 663 (e.g., VREF), the reference voltage 665 (e.g., V_IREF), and the signal 643 (e.g., EN). For example, the loop control circuit 638 for the DC-to-DC converter generates a control signal 639 (e.g., PWM) based at least in part on the voltage 631 (e.g., VIN_fb), the voltage 633 (e.g., VOUT_fb), the voltage 637 (e.g., V_Ifb), the reference voltage 663 (e.g., VREF), the reference voltage 665 (e.g., V_IREF), and the signal 643 (e.g., EN). As an example, the loop control circuit 638 for the DC-to-DC converter outputs the control signal 639 (e.g., PWM) to the gate driver 634 for the one or more transistor combinations 526.

According to certain embodiments, the gate driver 634 receives the control signal 639 (e.g., PWM) and generates the voltage 657 based at least in part on the control signal 639 (e.g., PWM) to turn on and/or turn off the transistor combination 526. In some examples, the transistor combination 526 is implemented as the transistor combination 400 as shown in FIG. 4. For example, the voltage 657 is used to turn on both the transistors 460 and 470 in order to turn on the transistor combination 526. As an example, the voltage 657 is used to turn off both the transistors 460 and 470 in order to turn off the transistor combination 526.

According to some embodiments, the loop control circuit 638 for the DC-to-DC converter receives the signal 643 (e.g., EN). For example, if the signal 643 (e.g., EN) is at the logic low level, the loop control circuit 638 for the DC-to-DC converter stops normal operation and the gate driver 634 generates the voltage 657 (e.g., at a logic low level) to turn off the transistor combination 526. As an example, if the signal 643 (e.g., EN) is at the logic high level, the loop control circuit 638 for the DC-to-DC converter operates normally.

In certain embodiments, the gate driver 644 for the one or more transistor combinations 574 receives the signal 645 (e.g., Switch_control) and generates the voltage 675 based at least in part on the signal 645 (e.g., Switch_control) to turn on and/or turn off the transistor combination 574. In some examples, the transistor combination 574 is implemented as the transistor combination 400 as shown in FIG. 4. For example, the voltage 675 is used to turn on both the transistors 460 and 470 in order to turn on the transistor combination 574. As an example, the voltage 675 is used to turn off both the transistors 460 and 470 in order to turn off the transistor combination 574. In certain examples, if the signal 645 (e.g., Switch_control) is at the logic low level, the gate driver 644 for the one or more transistor combinations 574 stops normal operation and generates the voltage 675 (e.g., at a logic low level) to turn off the transistor combination 574. As an example, if the gate driver 644 for the one or more transistor combinations 574 is at the logic high level, the gate driver 644 for the one or more transistor combinations 574 operates normally.

As mentioned above and further emphasized here, FIG. 5 is merely an example, which should not unduly limit the scope of the claims. One of ordinary skill in the art would recognize many variations, alternatives, and modifications. For example, the transistor-combination module 610 for a DC-to-DC converter includes multiple transistor combinations 526. As an example, the transistor-combination module 620 for one or more USB output ports includes multiple transistor combinations 574. For example, the fast-charging-protocol communication circuit 640 communicates with multiple loads 690.

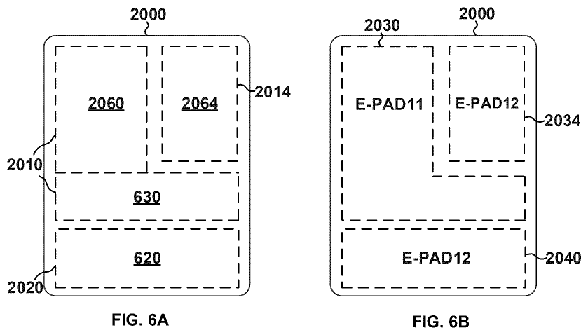

FIG. 6A and FIG. 6B are simplified diagrams showing a chip package of the fast-charging controller chip 500 as shown in FIG. 5 as part of the three-port USB fast charger 300 as shown in FIG. 3 according to some embodiments of the present disclosure. These diagrams are merely examples, which should not unduly limit the scope of the claims. One of ordinary skill in the art would recognize many variations, alternatives, and modifications. The chip package 2000 includes a chip base 2010, a chip base 2014, and a chip base 2020, and also includes a soldering pad 2030, a soldering pad 2034, and a soldering pad 2040. For example, the chip base 2010, the chip base 2014, and the chip base 2020 are electrically insulated from each other. Although the above has been shown using a selected group of components for the chip package, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to certain embodiments, the fast-charging controller chip 500 includes the transistor-combination module 610 for a DC-to-DC converter, the transistor-combination module 620 for one or more USB output ports, and the controller 630. In some embodiments, the transistor-combination module 610 for a DC-to-DC converter includes one or more high-side transistor combinations 2060 and one or more low-side transistor combinations 2064. For example, the one or more high-side transistor combinations 2060 include the high-side transistor combination 326, and the one or more low-side transistor combinations 2064 include the low-side transistor combination 328. As an example, the one or more high-side transistor combinations 2060 include the high-side transistor combination 336, and the one or more low-side transistor combinations 2064 include the low-side transistor combination 338.

In certain examples, the chip base 2010 is one side of a metal sheet, and another side of the metal sheet is the soldering pad 2030. For example, the one or more high-side transistor combinations 2060 of the transistor-combination module 610 for a DC-to-DC converter and the controller 630 are placed on the chip base 2010. As an example, the soldering pad 2030 (e.g., E-PAD 11) is used to connect the packaged chip (e.g., the fast-charging controller chip 500) to another device (e.g., a PCB board). In some examples, the chip base 2014 is one side of a metal sheet, and another side of the metal sheet is the soldering pad 2034. For example, the one or more low-side transistor combinations 2064 of the transistor-combination module 610 for a DC-to-DC converter are placed on the chip base 2014. As an example, the soldering pad 2034 (e.g., E-PAD 12) is used to connect the packaged chip (e.g., the fast-charging controller chip 500) to another device (e.g., a PCB board). In certain examples, the chip base 2020 is one side of a metal sheet, and another side of the metal sheet is the soldering pad 2040. For example, the transistor-combination module 620 for one or more USB output ports is placed on the chip base 2020. As an example, the soldering pad 2040 (e.g., E-PAD 13) is used to connect the packaged chip (e.g., the fast-charging controller chip 500) to another device (e.g., a PCB board).

In some embodiments, the metal sheet for the chip base 2010 and the soldering pad 2030 is electrically insulated from the metal sheet for the chip base 2020 and the soldering pad 2040, the metal sheet for the chip base 2020 and the soldering pad 2040 is electrically insulated from the metal sheet for the chip base 2014 and the soldering pad 2034, and the metal sheet for the chip base 2014 and the soldering pad 2034 is electrically insulated from the metal sheet for the chip base 2010 and the soldering pad 2030.

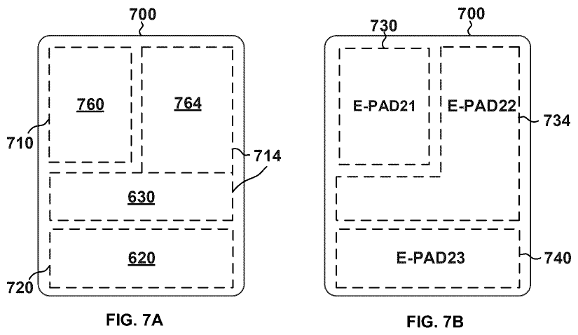

FIG. 7A and FIG. 7B are simplified diagrams showing a chip package of the fast-charging controller chip 500 as shown in FIG. 5 as part of the three-port USB fast charger 300 as shown in FIG. 3 according to certain embodiments of the present disclosure. These diagrams are merely examples, which should not unduly limit the scope of the claims. One of ordinary skill in the art would recognize many variations, alternatives, and modifications. The chip package 700 includes a chip base 710, a chip base 714, and a chip base 720, and also includes a soldering pad 730, a soldering pad 734, and a soldering pad 740. For example, the chip base 710, the chip base 714, and the chip base 720 are electrically insulated from each other. Although the above has been shown using a selected group of components for the chip package, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to some embodiments, the fast-charging controller chip 500 includes the transistor-combination module 610 for a DC-to-DC converter, the transistor-combination module 620 for one or more USB output ports, and the controller 630. In certain embodiments, the transistor-combination module 610 for a DC-to-DC converter includes one or more high-side transistor combinations 760 and one or more low-side transistor combinations 764. For example, the one or more high-side transistor combinations 760 include the high-side transistor combination 326, and the one or more low-side transistor combinations 764 include the low-side transistor combination 328. As an example, the one or more high-side transistor combinations 760 include the high-side transistor combination 336, and the one or more low-side transistor combinations 764 include the low-side transistor combination 338.

In some examples, the chip base 710 is one side of a metal sheet, and another side of the metal sheet is the soldering pad 730. For example, the one or more high-side transistor combinations 760 of the transistor-combination module 610 for a DC-to-DC converter are placed on the chip base 710. As an example, the soldering pad 730 (e.g., E-PAD 21) is used to connect the packaged chip (e.g., the fast-charging controller chip 500) to another device (e.g., a PCB board). In certain examples, the chip base 714 is one side of a metal sheet, and another side of the metal sheet is the soldering pad 734. For example, the one or more low-side transistor combinations 764 of the transistor-combination module 610 for a DC-to-DC converter and the controller 630 are placed on the chip base 714. As an example, the soldering pad 734 (e.g., E-PAD 22) is used to connect the packaged chip (e.g., the fast-charging controller chip 500) to another device (e.g., a PCB board). In certain examples, the chip base 720 is one side of a metal sheet, and another side of the metal sheet is the soldering pad 740. For example, the transistor-combination module 620 for one or more USB output ports is placed on the chip base 720. As an example, the soldering pad 740 (e.g., E-PAD 23) is used to connect the packaged chip (e.g., the fast-charging controller chip 500) to another device (e.g., a PCB board).

In some embodiments, the metal sheet for the chip base 710 and the soldering pad 730 is electrically insulated from the metal sheet for the chip base 720 and the soldering pad 740, the metal sheet for the chip base 720 and the soldering pad 740 is electrically insulated from the metal sheet for the chip base 714 and the soldering pad 734, and the metal sheet for the chip base 714 and the soldering pad 734 is electrically insulated from the metal sheet for the chip base 710 and the soldering pad 730.

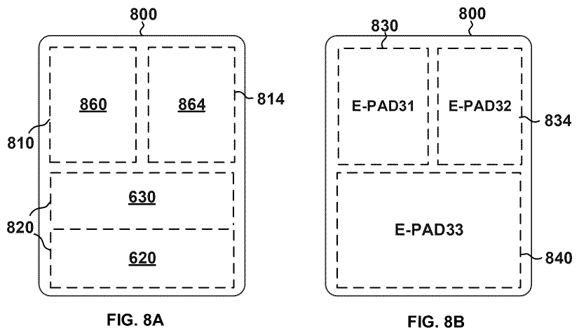

FIG. 8A and FIG. 8B are simplified diagrams showing a chip package of the fast-charging controller chip 500 as shown in FIG. 5 as part of the three-port USB fast charger 300 as shown in FIG. 3 according to some embodiments of the present disclosure. These diagrams are merely examples, which should not unduly limit the scope of the claims. One of ordinary skill in the art would recognize many variations, alternatives, and modifications. The chip package 800 includes a chip base 810, a chip base 814, and a chip base 820, and also includes a soldering pad 830, a soldering pad 834, and a soldering pad 840. For example, the chip base 810, the chip base 814, and the chip base 820 are electrically insulated from each other. Although the above has been shown using a selected group of components for the chip package, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to certain embodiments, the fast-charging controller chip 500 includes the transistor-combination module 610 for a DC-to-DC converter, the transistor-combination module 620 for one or more USB output ports, and the controller 630. In some embodiments, the transistor-combination module 610 for a DC-to-DC converter includes one or more high-side transistor combinations 860 and one or more low-side transistor combinations 864. For example, the one or more high-side transistor combinations 860 include the high-side transistor combination 326, and the one or more low-side transistor combinations 864 include the low-side transistor combination 328. As an example, the one or more high-side transistor combinations 860 include the high-side transistor combination 336, and the one or more low-side transistor combinations 864 include the low-side transistor combination 338.

In certain examples, the chip base 810 is one side of a metal sheet, and another side of the metal sheet is the soldering pad 830. For example, the one or more high-side transistor combinations 860 of the transistor-combination module 610 for a DC-to-DC converter are placed on the chip base 810. As an example, the soldering pad 830 (e.g., E-PAD 31) is used to connect the packaged chip (e.g., the fast-charging controller chip 500) to another device (e.g., a PCB board). In some examples, the chip base 814 is one side of a metal sheet, and another side of the metal sheet is the soldering pad 834. For example, the one or more low-side transistor combinations 864 of the transistor-combination module 610 for a DC-to-DC converter are placed on the chip base 814. As an example, the soldering pad 834 (e.g., E-PAD 32) is used to connect the packaged chip (e.g., the fast-charging controller chip 500) to another device (e.g., a PCB board). In certain examples, the chip base 820 is one side of a metal sheet, and another side of the metal sheet is the soldering pad 840. For example, the transistor-combination module 620 for one or more USB output ports and the controller 630 are placed on the chip base 820. As an example, the soldering pad 840 (e.g., E-PAD 33) is used to connect the packaged chip (e.g., the fast-charging controller chip 500) to another device (e.g., a PCB board).

In certain embodiments, the metal sheet for the chip base 810 and the soldering pad 830 is electrically insulated from the metal sheet for the chip base 820 and the soldering pad 840, the metal sheet for the chip base 820 and the soldering pad 840 is electrically insulated from the metal sheet for the chip base 814 and the soldering pad 834, and the metal sheet for the chip base 814 and the soldering pad 834 is electrically insulated from the metal sheet for the chip base 810 and the soldering pad 830.

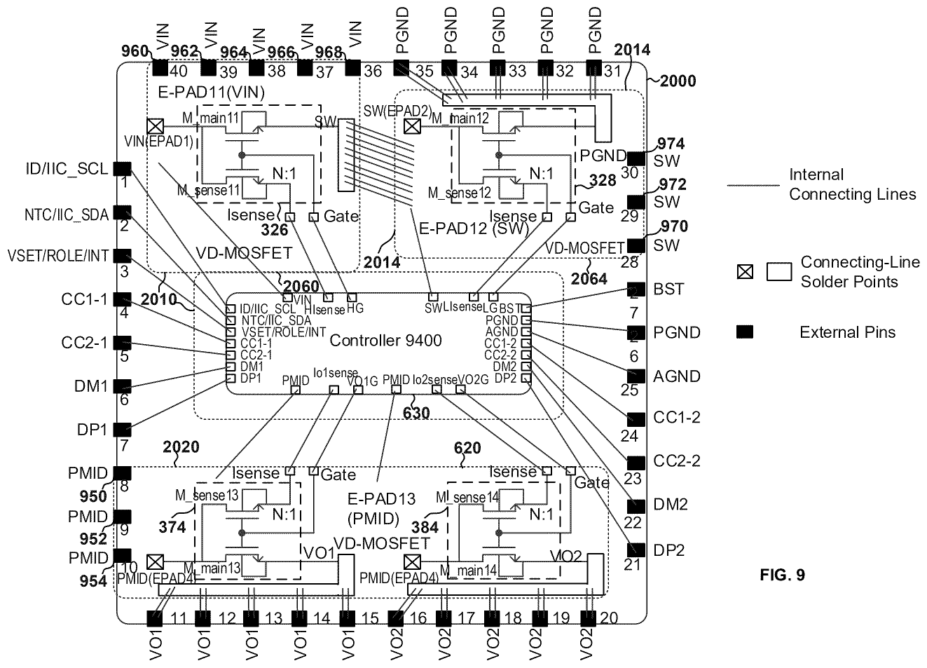

FIG. 9 is a simplified diagram showing certain components of the chip package 2000 as shown in FIG. 6A and FIG. 6B as part of the three-port USB fast charger 300 as shown in FIG. 3 according to some embodiments of the present disclosure. This diagram is merely an example, which should not unduly limit the scope of the claims. One of ordinary skill in the art would recognize many variations, alternatives, and modifications. The chip package 2000 includes pins 950, 952, 954, 960, 962, 964, 966, 968, 970, 972 and 974, and also includes the chip base 2010, the chip base 2014 and the chip base 2020. For example, the chip package 2000 includes the fast-charging controller chip 320. As an example, the chip package 2000 includes the fast-charging controller chip 330. Although the above has been shown using a selected group of components for the chip package, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to certain embodiments, the one or more high-side transistor combinations 2060 of the transistor-combination module 610 for a DC-to-DC converter and the controller 630 are placed on the chip base 2010, the one or more low-side transistor combinations 2064 of the transistor-combination module 610 for a DC-to-DC converter are placed on the chip base 2014, and the transistor-combination module 620 for one or more USB output ports is placed on the chip base 2020. For example, the one or more high-side transistor combinations 2060 of the transistor-combination module 610 for a DC-to-DC converter include the high-side transistor combination 326, and the one or more low-side transistor combinations 2064 of the transistor-combination module 610 for a DC-to-DC converter include the low-side transistor combination 328. As an example, the transistor-combination module 620 for one or more USB output ports includes the transistor combinations 374 and 384.

In some embodiments, each transistor combination of the one or more high-side transistor combinations 2060 of the transistor-combination module 610 for a DC-to-DC converter includes two vertically double-diffused metal-oxide-semiconductor field-effect transistors. For example, the transistor combination 326 includes two transistors 460 and 470 that are vertically double-diffused metal-oxide-semiconductor field-effect transistors, whose drains are bonded to the chip base 2010 through an electrically conductive adhesive. As an example, the transistor combination 336 includes two transistors 460 and 470 that are vertically double-diffused metal-oxide-semiconductor field-effect transistors, whose drains are bonded to the chip base 2010 through an electrically conductive adhesive.

In certain embodiments, each transistor combination of the one or more low-side transistor combinations 2064 of the transistor-combination module 610 for a DC-to-DC converter includes two vertically double-diffused metal-oxide-semiconductor field-effect transistors. For example, the transistor combination 328 includes two transistors 460 and 470 that are vertically double-diffused metal-oxide-semiconductor field-effect transistors, whose drains are bonded to the chip base 2014 through an electrically conductive adhesive. As an example, the transistor combination 338 includes two transistors 460 and 470 that are vertically double-diffused metal-oxide-semiconductor field-effect transistors, whose drains are bonded to the chip base 2014 through an electrically conductive adhesive.

In some embodiments, each transistor combination of the transistor-combination module 620 for one or more USB output ports includes two vertically double-diffused metal-oxide-semiconductor field-effect transistors. For example, the transistor combination 374 includes two transistors 460 and 470 that are vertically double-diffused metal-oxide-semiconductor field-effect transistors, whose drains are bonded to the chip base 2020 through an electrically conductive adhesive. As an example, the transistor combination 384 includes two transistors 460 and 470 that are vertically double-diffused metal-oxide-semiconductor field-effect transistors, whose drains are bonded to the chip base 2020 through an electrically conductive adhesive. For example, the transistor combination 394 includes two transistors 460 and 470 that are vertically double-diffused metal-oxide-semiconductor field-effect transistors, whose drains are bonded to the chip base 2020 through an electrically conductive adhesive.

According to some embodiments, the chip base 2010 is biased to a voltage VIN (e.g., the voltage 311). For example, for each transistor combination of the one or more high-side transistor combinations 2060 of the transistor-combination module 610 for a DC-to-DC converter, the drains of its two transistors (e.g., the transistor 460 and the transistor 470) are bonded to the chip base 2010 through an electrically conductive adhesive, and the chip base 2010 is biased to the same voltage as the drains of its two transistors (e.g., the transistor 460 and the transistor 470). As an example, each pin of the pins 960, 962, 964, 966 and 968 is electrically connected to the chip base 2010, and is biased to the voltage VIN, to which the chip base 2010 is also biased. In some examples, the chip base 2010 is biased to the voltage 311, the terminal 340 of the transistor combination 326 is biased to the voltage 311, and each pin of the pins 960, 962, 964, 966 and 968 is biased to the voltage 311. For example, each pin of the pins 960, 962, 964, 966 and 968 is biased to the same voltage 311 as the terminal 340 of the transistor combination 326 without using any electrically conductive connecting lines. In certain examples, the chip base 2010 is biased to the voltage 311, the terminal 364 of the transistor combination 336 is biased to the voltage 311, and each pin of the pins 960, 962, 964, 966 and 968 is biased to the voltage 311. As an example, each pin of the pins 960, 962, 964, 966 and 968 is biased to the same voltage 311 as the terminal 364 of the transistor combination 336 without using any electrically conductive connecting lines. In some examples, if the chip base 2010 is biased to the voltage VIN (e.g., the voltage 311), the controller 630 is bonded to the chip base 2010 through an electrically insulative adhesive. For example, the controller 630 includes an electrically conductive bottom surface, which is bonded to the chip base 2010 through the electrically insulative adhesive.

According to certain embodiments, the chip base 2014 is biased to a voltage SW (e.g., the voltage 313 and/or the voltage 317). For example, for each transistor combination of the one or more low-side transistor combinations 2064 of the transistor-combination module 610 for a DC-to-DC converter, the drains of its two transistors (e.g., the transistor 460 and the transistor 470) are bonded to the chip base 2014 through an electrically conductive adhesive, and the chip base 2014 is biased to the same voltage as the drains of its two transistors (e.g., the transistor 460 and the transistor 470). As an example, each pin of the pins 970, 972 and 974 is electrically connected to the chip base 2014, and is biased to the voltage SW, to which the chip base 2014 is also biased. In some examples, the chip base 2014 is biased to the voltage 313, the terminal 346 of the transistor combination 328 is biased to the voltage 313, and each pin of the pins 970, 972 and 974 is biased to the voltage 313. For example, each pin of the pins 970, 972 and 974 is biased to the same voltage 313 as the terminal 346 of the transistor combination 328 without using any electrically conductive connecting lines. In certain examples, the chip base 2014 is biased to the voltage 317, the terminal 372 of the transistor combination 338 is biased to the voltage 317, and each pin of the pins 970, 972 and 974 is biased to the voltage 317. As an example, each pin of the pins 970, 972 and 974 is biased to the same voltage 317 as the terminal 372 of the transistor combination 338 without using any electrically conductive connecting lines.

According to some embodiments, the chip base 2020 is biased to a voltage PMID (e.g., the voltage 371 and/or the voltage 391). For example, for each transistor combination of the transistor-combination module 620 for one or more USB output ports, the drains of its two transistors (e.g., the transistor 460 and the transistor 470) are bonded to the chip base 2020 through an electrically conductive adhesive, and the chip base 2020 is biased to the same voltage as the drains of its two transistors (e.g., the transistor 460 and the transistor 470). As an example, each pin of the pins 950, 952 and 954 is electrically connected to the chip base 2020, and is biased to the voltage PMID, to which the chip base 2020 is also biased. In some examples, the chip base 2020 is biased to the voltage 371, the terminal 352 of the transistor combination 374 is biased to the voltage 371, the terminal 358 of the transistor combination 384 is biased to the voltage 371, and each pin of the pins 950, 952 and 954 is biased to the voltage 371. For example, each pin of the pins 950, 952 and 954 is biased to the same voltage 371 as the terminal 352 of the transistor combination 374 and the terminal 358 of the transistor combination 384 without using any electrically conductive connecting lines. In certain examples, the chip base 2020 is biased to the voltage 391, the terminal 382 of the transistor combination 394 is biased to the voltage 391, and each pin of the pins 950, 952 and 954 is biased to the voltage 391. As an example, each pin of the pins 950, 952 and 954 is biased to the same voltage 391 as the terminal 382 of the transistor combination 394 without using any electrically conductive connecting lines.

In certain embodiments, the chip package 2000 includes multiple PMID pins (e.g., the pins 950, 952 and 954), multiple VIN pins (e.g., the pins 960, 962, 964, 966 and 968), and multiple SW pins (e.g., pins 970, 972 and 974). For example, each pin of the multiple PMID pins represents a pin for an output voltage (e.g., the voltage 371) of the DC-to-DC converter in the chip package 2000. As an example, each pin of the multiple VIN pins represents a pin for an input voltage (e.g., the voltage 311) of the DC-to-DC converter in the chip package 2000. For example, each pin of the multiple SW pins represents a pin for a node voltage (e.g., the voltage 313) between a high-side transistor combination (e.g., the high-side transistor combination 326) and a corresponding low-side transistor combination (e.g., the low-side transistor combination 328) of the DC-to-DC converter in the chip package 2000.

In some embodiments, the chip package 2000 also includes a BST pin, multiple PGND pins, an AGND pin, a CC1-1 pin, a CC1-2 pin, a CC2-1 pin, a CC2-2 pin, a DM1 pin, a DM2 pin, a DP1 pin, a DP2 pin, multiple VO1 pins, multiple VO2 pins, an ID/IIC_SCL pin, an NTC/IIC_SDA pin, and a VSET/ROLE/INT pin. For example, the BST pin represents a pin related to a bootstrap capacitor. As an example, each pin of the multiple PGND pins and the AGND pin represents a pin related to a reference ground voltage (e.g., the ground voltage 325). For example, each pin of the CC1-1 pin, the CC1-2 pin, the CC2-1 pin, the CC2-2 pin, the DM1 pin, the DM2 pin, the DP1 pin, the DP2 pin, the multiple VO1 pins, and the multiple VO2 pins is a pin related to a USB port (e.g., the USB output port 370 and/or the USB output port 380) that is supported by the chip package 2000. As an example, each pin of the ID/IIC_SCL pin, the NTC/IIC_SDA pin, and the VSET/ROLE/INT pin represents a pin related to the distribution of power from an AC-to-DC converter (e.g., the AC-to-DC converter 310) to the fast-charging controller chip (e.g., the fast-charging controller chip 320) in the chip package 2000.

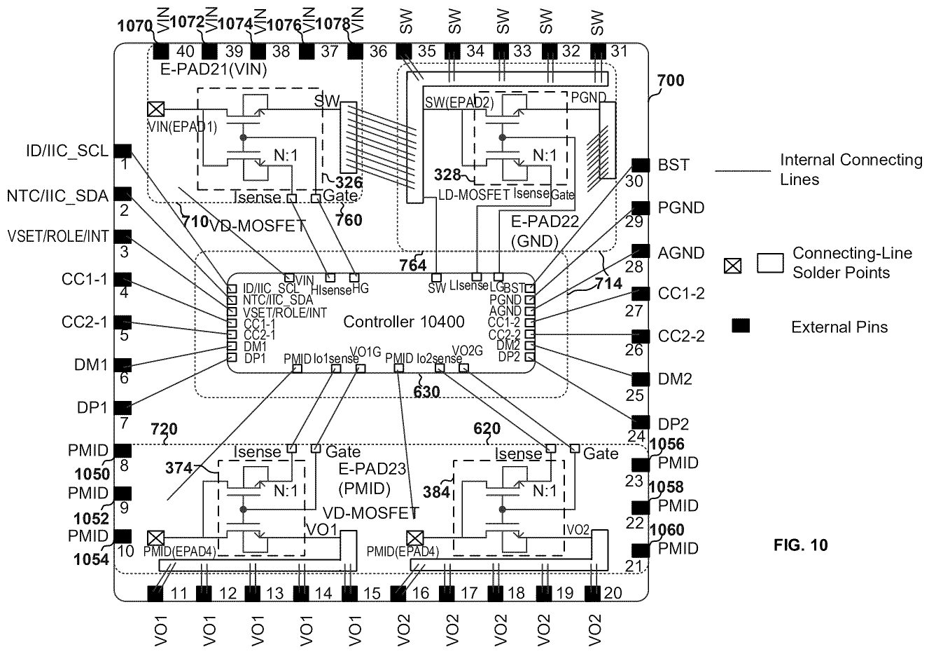

FIG. 10 is a simplified diagram showing certain components of the chip package 700 as shown in FIG. 7A and FIG. 7B as part of the three-port USB fast charger 300 as shown in FIG. 3 according to some embodiments of the present disclosure. This diagram is merely an example, which should not unduly limit the scope of the claims. One of ordinary skill in the art would recognize many variations, alternatives, and modifications. The chip package 700 includes pins 1050, 1052, 1054, 1056, 1058, 1060, 1070, 1072, 1074, 1076 and 1078, and also includes the chip base 710, the chip base 714 and the chip base 720. For example, the chip package 700 includes the fast-charging controller chip 320. As an example, the chip package 700 includes the fast-charging controller chip 330. Although the above has been shown using a selected group of components for the chip package, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to certain embodiments, the one or more high-side transistor combinations 760 of the transistor-combination module 610 for a DC-to-DC converter are placed on the chip base 710, the one or more low-side transistor combinations 764 of the transistor-combination module 610 for a DC-to-DC converter and the controller 630 are placed on the chip base 714, and the transistor-combination module 620 for one or more USB output ports is placed on the chip base 720. For example, the one or more high-side transistor combinations 760 of the transistor-combination module 610 for a DC-to-DC converter include the high-side transistor combination 326, and the one or more low-side transistor combinations 764 of the transistor-combination module 610 for a DC-to-DC converter include the low-side transistor combination 328. As an example, the transistor-combination module 620 for one or more USB output ports includes the transistor combinations 374 and 384.

In some embodiments, each transistor combination of the one or more high-side transistor combinations 760 of the transistor-combination module 610 for a DC-to-DC converter includes two vertically double-diffused metal-oxide-semiconductor field-effect transistors. For example, the transistor combination 326 includes two transistors 460 and 470 that are vertically double-diffused metal-oxide-semiconductor field-effect transistors, whose drains are bonded to the chip base 710 through an electrically conductive adhesive. As an example, the transistor combination 336 includes two transistors 460 and 470 that are vertically double-diffused metal-oxide-semiconductor field-effect transistors, whose drains are bonded to the chip base 710 through an electrically conductive adhesive.

In certain embodiments, each transistor combination of the one or more low-side transistor combinations 764 of the transistor-combination module 610 for a DC-to-DC converter includes two laterally double-diffused metal-oxide-semiconductor field-effect transistors. For example, the transistor combination 328 includes two transistors 460 and 470 that are laterally double-diffused metal-oxide-semiconductor field-effect transistors. As an example, the transistor combination 338 includes two transistors 460 and 470 that are laterally double-diffused metal-oxide-semiconductor field-effect transistors.

In some embodiments, each transistor combination of the transistor-combination module 620 for one or more USB output ports includes two vertically double-diffused metal-oxide-semiconductor field-effect transistors. For example, the transistor combination 374 includes two transistors 460 and 470 that are vertically double-diffused metal-oxide-semiconductor field-effect transistors, whose drains are bonded to the chip base 720 through an electrically conductive adhesive. As an example, the transistor combination 384 includes two transistors 460 and 470 that are vertically double-diffused metal-oxide-semiconductor field-effect transistors, whose drains are bonded to the chip base 720 through an electrically conductive adhesive. For example, the transistor combination 394 includes two transistors 460 and 470 that are vertically double-diffused metal-oxide-semiconductor field-effect transistors, whose drains are bonded to the chip base 720 through an electrically conductive adhesive.

According to some embodiments, the chip base 710 is biased to a voltage VIN (e.g., the voltage 311). For example, for each transistor combination of the one or more high-side transistor combinations 760 of the transistor-combination module 610 for a DC-to-DC converter, the drains of its two transistors (e.g., the transistor 460 and the transistor 470) are bonded to the chip base 710 through an electrically conductive adhesive, and the chip base 710 is biased to the same voltage as the drains of its two transistors (e.g., the transistor 460 and the transistor 470). As an example, each pin of the pins 1070, 1072, 1074, 1076 and 1078 is electrically connected to the chip base 710, and is biased to the voltage VIN, to which the chip base 710 is also biased. In some examples, the chip base 710 is biased to the voltage 311, the terminal 340 of the transistor combination 326 is biased to the voltage 311, and each pin of the pins 1070, 1072, 1074, 1076 and 1078 is biased to the voltage 311. For example, each pin of the pins 1070, 1072, 1074, 1076 and 1078 is biased to the same voltage 311 as the terminal 340 of the transistor combination 326 without using any electrically conductive connecting lines. In certain examples, the chip base 710 is biased to the voltage 311, the terminal 364 of the transistor combination 336 is biased to the voltage 311, and each pin of the pins 1070, 1072, 1074, 1076 and 1078 is biased to the voltage 311. As an example, each pin of the pins 1070, 1072, 1074, 1076 and 1078 is biased to the same voltage 311 as the terminal 364 of the transistor combination 336 without using any electrically conductive connecting lines.

According to certain embodiments, the chip base 714 is biased to a ground voltage (e.g., the ground voltage 325). In some examples, if the chip base 714 is biased to the ground voltage (e.g., the ground voltage 325), the controller 630 is bonded to the chip base 714 through an electrically conductive adhesive. For example, the controller 630 includes an electrically conductive bottom surface, which is bonded to the chip base 714 through the electrically conductive adhesive. As an example, the electrically conductive bottom surface of the controller 630 is biased to the ground voltage (e.g., the ground voltage 325) by the chip base 714 through the electrically conductive adhesive.

According to some embodiments, the chip base 720 is biased to a voltage PMID (e.g., the voltage 371 and/or the voltage 391). For example, for each transistor combination of the transistor-combination module 620 for one or more USB output ports, the drains of its two transistors (e.g., the transistor 460 and the transistor 470) are bonded to the chip base 720 through an electrically conductive adhesive, and the chip base 720 is biased to the same voltage as the drains of its two transistors (e.g., the transistor 460 and the transistor 470). As an example, each pin of the pins 1050, 1052, 1054, 1056, 1058 and 1060 is electrically connected to the chip base 720, and is biased to the voltage PMID, to which the chip base 720 is also biased. In some examples, the chip base 720 is biased to the voltage 371, the terminal 352 of the transistor combination 374 is biased to the voltage 371, the terminal 358 of the transistor combination 384 is biased to the voltage 371, and each pin of the pins 1050, 1052, 1054, 1056, 1058 and 1060 is biased to the voltage 371. For example, each pin of the pins 1050, 1052, 1054, 1056, 1058 and 1060 is biased to the same voltage 371 as the terminal 352 of the transistor combination 374 and the terminal 358 of the transistor combination 384 without using any electrically conductive connecting lines. In certain examples, the chip base 720 is biased to the voltage 391, the terminal 382 of the transistor combination 394 is biased to the voltage 391, and each pin of the pins 1050, 1052, 1054, 1056, 1058 and 1060 is biased to the voltage 391. As an example, each pin of the pins 1050, 1052, 1054, 1056, 1058 and 1060 is biased to the same voltage 391 as the terminal 382 of the transistor combination 394 without using any electrically conductive connecting lines.

In certain embodiments, the chip package 700 includes multiple PMID pins (e.g., the pins 1050, 1052, 1054, 1056, 1058 and 1060) and multiple VIN pins (e.g., the pins 1070, 1072, 1074, 1076 and 1078). For example, each pin of the multiple PMID pins represents a pin for an output voltage (e.g., the voltage 371) of the DC-to-DC converter in the chip package 700. As an example, each pin of the multiple VIN pins represents a pin for an input voltage (e.g., the voltage 311) of the DC-to-DC converter in the chip package 700.

In some embodiments, the chip package 700 also includes multiple SW pins, a BST pin, a PGND pin, an AGND pin, a CC1-1 pin, a CC1-2 pin, a CC2-1 pin, a CC2-2 pin, a DM1 pin, a DM2 pin, a DP1 pin, a DP2 pin, multiple VO1 pins, multiple VO2 pins, an ID/IIC_SCL pin, an NTC/IIC_SDA pin, and a VSET/ROLE/INT pin. For example, each pin of the multiple SW pins represents a pin for a node voltage (e.g., the voltage 313) between a high-side transistor combination (e.g., the high-side transistor combination 326) and a corresponding low-side transistor combination (e.g., the low-side transistor combination 328) of the DC-to-DC converter in the chip package 700. As an example, the BST pin represents a pin related to a bootstrap capacitor. For example, each pin of the PGND pin and the AGND pin represents a pin related to a reference ground voltage (e.g., the ground voltage 325). As an example, each pin of the CC1-1 pin, the CC1-2 pin, the CC2-1 pin, the CC2-2 pin, the DM1 pin, the DM2 pin, the DP1 pin, the DP2 pin, the multiple VO1 pins, and the multiple VO2 pins is a pin related to a USB port (e.g., the USB output port 370 and/or the USB output port 380) that is supported by the chip package 700. As an example, each pin of the ID/IIC_SCL pin, the NTC/IIC_SDA pin, and the VSET/ROLE/INT pin represents a pin related to the distribution of power from an AC-to-DC converter (e.g., the AC-to-DC converter 310) to the fast-charging controller chip (e.g., the fast-charging controller chip 320) in the chip package 700.

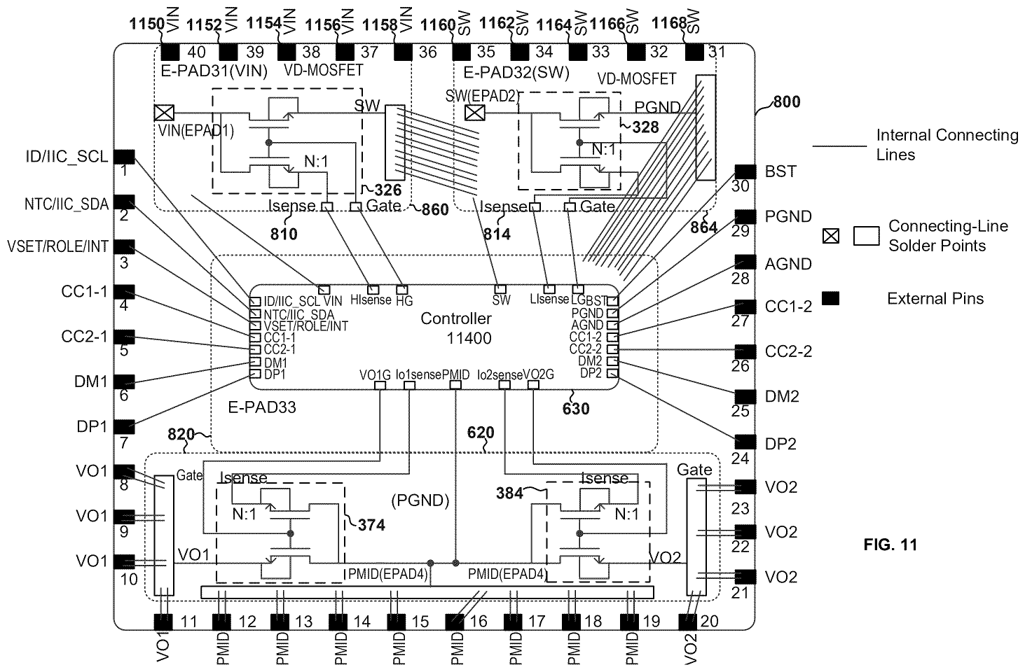

FIG. 11 is a simplified diagram showing certain components of the chip package 800 as shown in FIG. 8A and FIG. 8B as part of the three-port USB fast charger 300 as shown in FIG. 3 according to some embodiments of the present disclosure. This diagram is merely an example, which should not unduly limit the scope of the claims. One of ordinary skill in the art would recognize many variations, alternatives, and modifications. The chip package 800 includes pins 1150, 1152, 1154, 1156, 1158, 1160, 1162, 1164, 1166 and 1168, and also includes the chip base 810, the chip base 814 and the chip base 820. For example, the chip package 800 includes the fast-charging controller chip 320. As an example, the chip package 800 includes the fast-charging controller chip 330. Although the above has been shown using a selected group of components for the chip package, there can be many alternatives, modifications, and variations. For example, some of the components may be expanded and/or combined. Other components may be inserted to those noted above. Depending upon the embodiment, the arrangement of components may be interchanged with others replaced. Further details of these components are found throughout the present specification.

According to certain embodiments, the one or more high-side transistor combinations 860 of the transistor-combination module 610 for a DC-to-DC converter are placed on the chip base 810, the one or more low-side transistor combinations 864 of the transistor-combination module 610 for a DC-to-DC converter are placed on the chip base 814, and the transistor-combination module 620 for one or more USB output ports and the controller 630 is placed on the chip base 820. For example, the one or more high-side transistor combinations 860 of the transistor-combination module 610 for a DC-to-DC converter include the high-side transistor combination 326, and the one or more low-side transistor combinations 864 of the transistor-combination module 610 for a DC-to-DC converter include the low-side transistor combination 328. As an example, the transistor-combination module 620 for one or more USB output ports includes the transistor combinations 374 and 384.

In some embodiments, each transistor combination of the one or more high-side transistor combinations 860 of the transistor-combination module 610 for a DC-to-DC converter includes two vertically double-diffused metal-oxide-semiconductor field-effect transistors. For example, the transistor combination 326 includes two transistors 460 and 470 that are vertically double-diffused metal-oxide-semiconductor field-effect transistors, whose drains are bonded to the chip base 810 through an electrically conductive adhesive. As an example, the transistor combination 336 includes two transistors 460 and 470 that are vertically double-diffused metal-oxide-semiconductor field-effect transistors, whose drains are bonded to the chip base 810 through an electrically conductive adhesive.

In certain embodiments, each transistor combination of the one or more low-side transistor combinations 864 of the transistor-combination module 610 for a DC-to-DC converter includes two vertically double-diffused metal-oxide-semiconductor field-effect transistors. For example, the transistor combination 328 includes two transistors 460 and 470 that are vertically double-diffused metal-oxide-semiconductor field-effect transistors, whose drains are bonded to the chip base 814 through an electrically conductive adhesive. As an example, the transistor combination 338 includes two transistors 460 and 470 that are vertically double-diffused metal-oxide-semiconductor field-effect transistors, whose drains are bonded to the chip base 814 through an electrically conductive adhesive.

In some embodiments, each transistor combination of the transistor-combination module 620 for one or more USB output ports includes two laterally double-diffused metal-oxide-semiconductor field-effect transistors. For example, the transistor combination 374 includes two transistors 460 and 470 that are laterally double-diffused metal-oxide-semiconductor field-effect transistors. As an example, the transistor combination 384 includes two transistors 460 and 470 that are laterally double-diffused metal-oxide-semiconductor field-effect transistors. For example, the transistor combination 394 includes two transistors 460 and 470 that are laterally double-diffused metal-oxide-semiconductor field-effect transistors.

According to some embodiments, the chip base 810 is biased to a voltage VIN (e.g., the voltage 311). For example, for each transistor combination of the one or more high-side transistor combinations 860 of the transistor-combination module 610 for a DC-to-DC converter, the drains of its two transistors (e.g., the transistor 460 and the transistor 470) are bonded to the chip base 810 through an electrically conductive adhesive, and the chip base 810 is biased to the same voltage as the drains of its two transistors (e.g., the transistor 460 and the transistor 470). As an example, each pin of the pins 1150, 1152, 1154, 1156 and 1158 is electrically connected to the chip base 810, and is biased to the voltage VIN, to which the chip base 810 is also biased. In some examples, the chip base 810 is biased to the voltage 311, the terminal 340 of the transistor combination 326 is biased to the voltage 311, and each pin of the pins 1150, 1152, 1154, 1156 and 1158 is biased to the voltage 311. For example, each pin of the pins 1150, 1152, 1154, 1156 and 1158 is biased to the same voltage 311 as the terminal 340 of the transistor combination 326 without using any electrically conductive connecting lines. In certain examples, the chip base 810 is biased to the voltage 311, the terminal 364 of the transistor combination 336 is biased to the voltage 311, and each pin of the pins 1150, 1152, 1154, 1156 and 1158 is biased to the voltage 311. As an example, each pin of the pins 1150, 1152, 1154, 1156 and 1158 is biased to the same voltage 311 as the terminal 364 of the transistor combination 336 without using any electrically conductive connecting lines.

According to certain embodiments, the chip base 814 is biased to a voltage SW (e.g., the voltage 313 and/or the voltage 317). For example, for each transistor combination of the one or more low-side transistor combinations 864 of the transistor-combination module 610 for a DC-to-DC converter, the drains of its two transistors (e.g., the transistor 460 and the transistor 470) are bonded to the chip base 814 through an electrically conductive adhesive, and the chip base 814 is biased to the same voltage as the drains of its two transistors (e.g., the transistor 460 and the transistor 470). As an example, each pin of the pins 1160, 1162, 1164, 1166 and 1168 is electrically connected to the chip base 814, and is biased to the voltage SW, to which the chip base 814 is also biased. In some examples, the chip base 814 is biased to the voltage 313, the terminal 346 of the transistor combination 328 is biased to the voltage 313, and each pin of the pins 1160, 1162, 1164, 1166 and 1168 is biased to the voltage 313. For example, each pin of the pins 1160, 1162, 1164, 1166 and 1168 is biased to the same voltage 313 as the terminal 346 of the transistor combination 328 without using any electrically conductive connecting lines. In certain examples, the chip base 814 is biased to the voltage 317, the terminal 372 of the transistor combination 338 is biased to the voltage 317, and each pin of the pins 1160, 1162, 1164, 1166 and 1168 is biased to the voltage 317. As an example, each pin of the pins 1160, 1162, 1164, 1166 and 1168 is biased to the same voltage 317 as the terminal 372 of the transistor combination 338 without using any electrically conductive connecting lines.

According to some embodiments, the chip base 820 is biased to a ground voltage (e.g., the ground voltage 325). In some examples, if the chip base 820 is biased to the ground voltage (e.g., the ground voltage 325), the controller 630 is bonded to the chip base 820 through an electrically conductive adhesive. For example, the controller 630 includes an electrically conductive bottom surface, which is bonded to the chip base 820 through the electrically conductive adhesive. As an example, the electrically conductive bottom surface of the controller 630 is biased to the ground voltage (e.g., the ground voltage 325) by the chip base 820 through the electrically conductive adhesive.

In certain embodiments, the chip package 800 includes multiple VIN pins (e.g., the pins 1150, 1152, 1154, 1156 and 1158) and multiple SW pins (e.g., the pins 1160, 1162, 1164, 1166 and 1168). For example, each pin of the multiple VIN pins represents a pin for an input voltage (e.g., the voltage 311) of the DC-to-DC converter in the chip package 800. As an example, each pin of the multiple SW pins represents a pin for a node voltage (e.g., the voltage 313) between a high-side transistor combination (e.g., the high-side transistor combination 326) and a corresponding low-side transistor combination (e.g., the low-side transistor combination 328) of the DC-to-DC converter in the chip package 800.

In some embodiments, the chip package 800 also includes multiple PMID pins, a BST pin, a PGND pin, an AGND pin, a CC1-1 pin, a CC1-2 pin, a CC2-1 pin, a CC2-2 pin, a DM1 pin, a DM2 pin, a DP1 pin, a DP2 pin, multiple VO1 pins, multiple VO2 pins, an ID/IIC_SCL pin, an NTC/IIC_SDA pin, and a VSET/ROLE/INT pin. For example, each pin of the multiple PMID pins represents a pin for an output voltage (e.g., the voltage 371) of the DC-to-DC converter in the chip package 800. As an example, the BST pin represents a pin related to a bootstrap capacitor. For example, each pin of the PGND pin and the AGND pin represents a pin related to a reference ground voltage (e.g., the ground voltage 325). As an example, each pin of the CC1-1 pin, the CC1-2 pin, the CC2-1 pin, the CC2-2 pin, the DM1 pin, the DM2 pin, the DP1 pin, the DP2 pin, the multiple VO1 pins, and the multiple VO2 pins is a pin related to a USB port (e.g., the USB output port 370 and/or the USB output port 380) that is supported by the chip package 800. As an example, each pin of the ID/IIC_SCL pin, the NTC/IIC_SDA pin, and the VSET/ROLE/INT pin represents a pin related to the distribution of power from an AC-to-DC converter (e.g., the AC-to-DC converter 310) to the fast-charging controller chip (e.g., the fast-charging controller chip 320) in the chip package 800.

As discussed above and further emphasized here, FIG. 11 is merely an example, which should not unduly limit the scope of the claims. One of ordinary skill in the art would recognize many variations, alternatives, and modifications. In some embodiments, the chip base 810 is biased to a voltage VIN (e.g., the voltage 311), the chip base 814 is biased to a voltage SW (e.g., the voltage 313 and/or the voltage 317), and the chip base 820 is biased to a voltage PMID (e.g., the voltage 371 and/or the voltage 391). In certain examples, each transistor combination of the one or more high-side transistor combinations 860 of the transistor-combination module 610 for a DC-to-DC converter includes two vertically double-diffused metal-oxide-semiconductor field-effect transistors, each transistor combination of the one or more low-side transistor combinations 864 of the transistor-combination module 610 for a DC-to-DC converter includes two vertically double-diffused metal-oxide-semiconductor field-effect transistors, and each transistor combination of the transistor-combination module 620 for one or more USB output ports includes two vertically double-diffused metal-oxide-semiconductor field-effect transistors. For example, the transistor combination 374 includes two transistors 460 and 470 that are vertically double-diffused metal-oxide-semiconductor field-effect transistors, whose drains are bonded to the chip base 820 through an electrically conductive adhesive. As an example, the transistor combination 384 includes two transistors 460 and 470 that are vertically double-diffused metal-oxide-semiconductor field-effect transistors, whose drains are bonded to the chip base 820 through an electrically conductive adhesive. For example, for each transistor combination of the transistor-combination module 620 for one or more USB output ports, the drains of its two transistors (e.g., the transistor 460 and the transistor 470) are bonded to the chip base 820 through an electrically conductive adhesive, and the chip base 820 is biased to the same voltage as the drains of its two transistors (e.g., the transistor 460 and the transistor 470). As an example, each pin of the multiple PMID pins is electrically connected to the chip base 820, and is biased to the voltage PMID, to which the chip base 820 is also biased. In some examples, the chip base 820 is biased to the voltage 371, the terminal 352 of the transistor combination 374 is biased to the voltage 371, the terminal 358 of the transistor combination 384 is biased to the voltage 371, and each pin of the multiple PMID pins is biased to the voltage 371. For example, each pin of the multiple PMID pins is biased to the same voltage 371 as the terminal 352 of the transistor combination 374 and the terminal 358 of the transistor combination 384 without using any electrically conductive connecting lines. In certain examples, the chip base 820 is biased to the voltage 391, the terminal 382 of the transistor combination 394 is biased to the voltage 391, and each pin of the multiple PMID pins is biased to the voltage 391. As an example, each pin of the multiple PMID pins is biased to the same voltage 391 as the terminal 382 of the transistor combination 394 without using any electrically conductive connecting lines. In certain embodiments, if the chip base 820 is biased to a voltage PMID (e.g., the voltage 371 and/or the voltage 391), the controller 630 is bonded to the chip base 820 through an electrically insulative adhesive. For example, the controller 630 includes an electrically conductive bottom surface, which is bonded to the chip base 820 through the electrically insulative adhesive.

According to some embodiments, the present disclosure provides a USB fast charger that includes one or more fast-charging controller chips, wherein for each transistor combination, a current that flows through a main transistor is determined by using a sensing transistor without including a resistor that is in series with the main transistor, in order to lower the costs of the one or more fast-charging controller chips and/or reduce the size of the one or more fast-charging controller chips, as shown in FIG. 3, FIG. 4, FIG. 5, FIG. 6A, FIG. 6B, FIG. 7A, FIG. 7B, FIG. 8A, FIG. 8B, FIG. 9, FIG. 10 and/or FIG. 11.

According to some embodiments, the present disclosure provides a USB fast charger that includes one or more fast-charging controller chips, wherein for each fast-charging controller chip, the number of electrically conductive connecting lines is significantly reduced, in order to lower heat generation and facilitate heat dissipation, thus reducing the risk of overheating of the fast-charging controller chip and also improving energy efficiency of the fast-charging controller chip, as shown in FIG. 3, FIG. 4, FIG. 5, FIG. 6A, FIG. 6B, FIG. 7A, FIG. 7B, FIG. 8A, FIG. 8B, FIG. 9, FIG. 10 and/or FIG. 11.

According to certain embodiments, a chip package of a charging controller chip for a USB charger includes: a high-side transistor including a first drain, a first gate and a first source; a low-side transistor including a second drain, a second gate and a second source, the low-side transistor being connected to the high-side transistor; one or more port transistors corresponding to one or more USB output ports respectively, each port transistor of the one or more port transistors including a third drain, a third gate and a third source; a controller coupled to the high-side transistor, the low-side transistor, and the one or more port transistors; a first chip base; a second chip base electrically insulated from the first chip base; and a third chip base electrically insulated from the first chip base and electrically insulated from the second chip base; wherein: the one or more port transistors are located on the first chip base; the high-side transistor and the controller are located on the second chip base; and the low-side transistor is located on the third chip base. For example, the chip package is implemented according to at least FIG. 3, FIG. 4, FIG. 5, FIG. 6A, FIG. 6B, and/or FIG. 9.

As an example, the high-side transistor is apart of a high-side transistor combination that is located on the second chip base; the low-side transistor is a part of a low-side transistor combination that is located on the third chip base; and each port transistor of the one or more port transistors is a part of a port transistor combination that is located on the first chip base. For example, the high-side transistor combination includes the high-side transistor and a sensing transistor including a fourth drain, a fourth gate and a fourth source; wherein: the first drain of the high-side transistor and the fourth drain of the sensing transistor are connected; and the first gate of the high-side transistor and the fourth gate of the sensing transistor are connected. As an example, the low-side transistor combination includes the low-side transistor and a sensing transistor including a fourth drain, a fourth gate and a fourth source; wherein: the second drain of the low-side transistor and the fourth drain of the sensing transistor are connected; and the second gate of the low-side transistor and the fourth gate of the sensing transistor are connected. For example, the port transistor combination includes a port transistor of the one or more port transistors and a sensing transistor including a fourth drain, a fourth gate and a fourth source; wherein: the third drain of the port transistor and the fourth drain of the sensing transistor are connected; and the third gate of the port transistor and the fourth gate of the sensing transistor are connected.

As an example, the first chip base and the third drain are biased to a first voltage. For example, the second chip base and the first drain are biased to a second voltage. As an example, the controller is bonded to the second chip base through an electrically insulative adhesive. For example, the third chip base, the first source and the second drain are biased to a third voltage. As an example, each port transistor of the one or more port transistors is a first vertically double-diffused metal-oxide-semiconductor field-effect transistor. For example, the high-side transistor is a second vertically double-diffused metal-oxide-semiconductor field-effect transistor. As an example, the low-side transistor is a third vertically double-diffused metal-oxide-semiconductor field-effect transistor. For example, each port transistor of the one or more port transistors corresponds to a USB output port of the one or more USB output ports, the USB output port being configured to be connected to a load.

According to some embodiments, a chip package of a charging controller chip for a USB charger includes: a high-side transistor including a first drain, a first gate and a first source; a low-side transistor including a second drain, a second gate and a second source, the low-side transistor being connected to the high-side transistor; one or more port transistors corresponding to one or more USB output ports respectively, each port transistor of the one or more port transistors including a third drain, a third gate and a third source; a controller coupled to the high-side transistor, the low-side transistor, and the one or more port transistors; a first chip base; a second chip base electrically insulated from the first chip base; and a third chip base electrically insulated from the first chip base and electrically insulated from the second chip base; wherein: the one or more port transistors are located on the first chip base; the high-side transistor is located on the second chip base; and the low-side transistor and the controller are located on the third chip base. For example, the chip package is implemented according to at least FIG. 3, FIG. 4, FIG. 5, FIG. 7A, FIG. 7B, and/or FIG. 10.

As an example, the high-side transistor is apart of a high-side transistor combination that is located on the second chip base; the low-side transistor is a part of a low-side transistor combination that is located on the third chip base; and each port transistor of the one or more port transistors is a part of a port transistor combination that is located on the first chip base. For example, the high-side transistor combination includes the high-side transistor and a sensing transistor including a fourth drain, a fourth gate and a fourth source; wherein: the first drain of the high-side transistor and the fourth drain of the sensing transistor are connected; and the first gate of the high-side transistor and the fourth gate of the sensing transistor are connected. As an example, the low-side transistor combination includes the low-side transistor and a sensing transistor including a fourth drain, a fourth gate and a fourth source; wherein: the second drain of the low-side transistor and the fourth drain of the sensing transistor are connected; and the second gate of the low-side transistor and the fourth gate of the sensing transistor are connected. For example, the port transistor combination includes a port transistor of the one or more port transistors and a sensing transistor including a fourth drain, a fourth gate and a fourth source; wherein: the third drain of the port transistor and the fourth drain of the sensing transistor are connected; and the third gate of the port transistor and the fourth gate of the sensing transistor are connected.

As an example, the first chip base and the third drain are biased to a first voltage. For example, the second chip base and the first drain are biased to a second voltage. As an example, the third chip base and the second source are biased to a third voltage. For example, the controller is bonded to the third chip base through an electrically conductive adhesive. As an example, each port transistor of the one or more port transistors is a first vertically double-diffused metal-oxide-semiconductor field-effect transistor. For example, the high-side transistor is a second vertically double-diffused metal-oxide-semiconductor field-effect transistor. As an example, the low-side transistor is a laterally double-diffused metal-oxide-semiconductor field-effect transistor. For example, each port transistor of the one or more port transistors corresponds to a USB output port of the one or more USB output ports, the USB output port being configured to be connected to a load.

According to certain embodiments, a chip package of a charging controller chip for a USB charger includes: a high-side transistor including a first drain, a first gate and a first source; a low-side transistor including a second drain, a second gate and a second source, the low-side transistor being connected to the high-side transistor; one or more port transistors corresponding to one or more USB output ports respectively, each port transistor of the one or more port transistors including a third drain, a third gate and a third source; a controller coupled to the high-side transistor, the low-side transistor, and the one or more port transistors; a first chip base; a second chip base electrically insulated from the first chip base; and a third chip base electrically insulated from the first chip base and electrically insulated from the second chip base; wherein: the one or more port transistors and the controller are located on the first chip base; the high-side transistor is located on the second chip base; and the low-side transistor is located on the third chip base. For example, the chip package is implemented according to at least FIG. 3, FIG. 4, FIG. 5, FIG. 8A, FIG. 8B, and/or FIG. 11.

As an example, the high-side transistor is apart of a high-side transistor combination that is located on the second chip base; the low-side transistor is a part of a low-side transistor combination that is located on the third chip base; and each port transistor of the one or more port transistors is a part of a port transistor combination that is located on the first chip base. For example, the high-side transistor combination includes the high-side transistor and a sensing transistor including a fourth drain, a fourth gate and a fourth source; wherein: the first drain of the high-side transistor and the fourth drain of the sensing transistor are connected; and the first gate of the high-side transistor and the fourth gate of the sensing transistor are connected. As an example, the low-side transistor combination includes the low-side transistor and a sensing transistor including a fourth drain, a fourth gate and a fourth source; wherein: the second drain of the low-side transistor and the fourth drain of the sensing transistor are connected; and the second gate of the low-side transistor and the fourth gate of the sensing transistor are connected. For example, the port transistor combination includes a port transistor of the one or more port transistors and a sensing transistor including a fourth drain, a fourth gate and a fourth source; wherein: the third drain of the port transistor and the fourth drain of the sensing transistor are connected; and the third gate of the port transistor and the fourth gate of the sensing transistor are connected.

As an example, the first chip base and the second source are biased to a first voltage. For example, the controller is bonded to the first chip base through an electrically conductive adhesive. As an example, the second chip base and the first drain are biased to a second voltage. For example, the third chip base, the first source and the second drain are biased to a third voltage. As an example, each port transistor of the one or more port transistors is a laterally double-diffused metal-oxide-semiconductor field-effect transistor. For example, the high-side transistor is a first vertically double-diffused metal-oxide-semiconductor field-effect transistor. As an example, the low-side transistor is a second vertically double-diffused metal-oxide-semiconductor field-effect transistor.

For example, the first chip base and the third drain are biased to a first voltage. As an example, the controller is bonded to the first chip base through an electrically insulative adhesive. For example, the second chip base and the first drain are biased to a second voltage. As an example, the third chip base, the first source and the second drain are biased to a third voltage. For example, each port transistor of the one or more port transistors is a first vertically double-diffused metal-oxide-semiconductor field-effect transistor. As an example, the high-side transistor is a second vertically double-diffused metal-oxide-semiconductor field-effect transistor. For example, the low-side transistor is a third vertically double-diffused metal-oxide-semiconductor field-effect transistor. As an example, each port transistor of the one or more port transistors corresponds to a USB output port of the one or more USB output ports, the USB output port being configured to be connected to a load.

For example, some or all components of various embodiments of the present disclosure each are, individually and/or in combination with at least another component, implemented using one or more software components, one or more hardware components, and/or one or more combinations of software and hardware components. As an example, some or all components of various embodiments of the present disclosure each are, individually and/or in combination with at least another component, implemented in one or more circuits, such as one or more analog circuits and/or one or more digital circuits. For example, various embodiments and/or examples of the present disclosure can be combined.

Although specific embodiments of the present disclosure have been described, it will be understood by those of skill in the art that there are other embodiments that are equivalent to the described embodiments. Accordingly, it is to be understood that the invention is not to be limited by the specific illustrated embodiments.

What is claimed is:

1. A chip package of a charging controller chip for a USB charger, the chip package comprising:
a high-side transistor including a first drain, a first gate and a first source;
a low-side transistor including a second drain, a second gate and a second source, the low-side transistor being connected to the high-side transistor;
one or more port transistors corresponding to one or more USB output ports respectively, each port transistor of the one or more port transistors including a third drain, a third gate and a third source;
a controller coupled to the high-side transistor, the low-side transistor, and the one or more port transistors;
a first chip base;
a second chip base electrically insulated from the first chip base; and
a third chip base electrically insulated from the first chip base and electrically insulated from the second chip base;
wherein:
the one or more port transistors are located on the first chip base;
the high-side transistor and the controller are located on the second chip base; and
the low-side transistor is located on the third chip base.

2. The chip package of claim 1 wherein:
the high-side transistor is a part of a high-side transistor combination that is located on the second chip base;
the low-side transistor is a part of a low-side transistor combination that is located on the third chip base; and
each port transistor of the one or more port transistors is a part of a port transistor combination that is located on the first chip base.

3. The chip package of claim 2 wherein:
the high-side transistor combination includes the high-side transistor and a sensing transistor including a fourth drain, a fourth gate and a fourth source;
wherein:
the first drain of the high-side transistor and the fourth drain of the sensing transistor are connected; and
the first gate of the high-side transistor and the fourth gate of the sensing transistor are connected.

4. The chip package of claim 2 wherein:
the low-side transistor combination includes the low-side transistor and a sensing transistor including a fourth drain, a fourth gate and a fourth source;
wherein:
the second drain of the low-side transistor and the fourth drain of the sensing transistor are connected; and
the second gate of the low-side transistor and the fourth gate of the sensing transistor are connected.

5. The chip package of claim 2 wherein:
the port transistor combination includes a port transistor of the one or more port transistors and a sensing transistor including a fourth drain, a fourth gate and a fourth source;
wherein:
the third drain of the port transistor and the fourth drain of the sensing transistor are connected; and
the third gate of the port transistor and the fourth gate of the sensing transistor are connected.

6. The chip package of claim 1 wherein the first chip base and the third drain are biased to a first voltage.

7. The chip package of claim 6 wherein the second chip base and the first drain are biased to a second voltage.

8. The chip package of claim 7 wherein the controller is bonded to the second chip base through an electrically insulative adhesive.

9. The chip package of claim 7 wherein the third chip base, the first source and the second drain are biased to a third voltage.

10. The chip package of claim 9 wherein each port transistor of the one or more port transistors is a first vertically double-diffused metal-oxide-semiconductor field-effect transistor.

11. The chip package of claim 10 wherein the high-side transistor is a second vertically double-diffused metal-oxide-semiconductor field-effect transistor.

12. The chip package of claim 11 wherein the low-side transistor is a third vertically double-diffused metal-oxide-semiconductor field-effect transistor.

13. The chip package of claim 1 wherein each port transistor of the one or more port transistors corresponds to a USB output port of the one or more USB output ports, the USB output port being configured to be connected to a load.

14. A chip package of a charging controller chip for a USB charger, the chip package comprising:
a high-side transistor including a first drain, a first gate and a first source;
a low-side transistor including a second drain, a second gate and a second source, the low-side transistor being connected to the high-side transistor;
one or more port transistors corresponding to one or more USB output ports respectively, each port transistor of the one or more port transistors including a third drain, a third gate and a third source;
a controller coupled to the high-side transistor, the low-side transistor, and the one or more port transistors;
a first chip base;
a second chip base electrically insulated from the first chip base; and
a third chip base electrically insulated from the first chip base and electrically insulated from the second chip base;
wherein:
the one or more port transistors are located on the first chip base;
the high-side transistor is located on the second chip base; and
the low-side transistor and the controller are located on the third chip base.

15. The chip package of claim 14 wherein:
the high-side transistor is a part of a high-side transistor combination that is located on the second chip base;
the low-side transistor is a part of a low-side transistor combination that is located on the third chip base; and
each port transistor of the one or more port transistors is a part of a port transistor combination that is located on the first chip base.

16. The chip package of claim 15 wherein:
the high-side transistor combination includes the high-side transistor and a sensing transistor including a fourth drain, a fourth gate and a fourth source;
wherein:
the first drain of the high-side transistor and the fourth drain of the sensing transistor are connected; and
the first gate of the high-side transistor and the fourth gate of the sensing transistor are connected.

17. The chip package of claim 15 wherein:
the low-side transistor combination includes the low-side transistor and a sensing transistor including a fourth drain, a fourth gate and a fourth source;
wherein:
the second drain of the low-side transistor and the fourth drain of the sensing transistor are connected; and
the second gate of the low-side transistor and the fourth gate of the sensing transistor are connected.

18. The chip package of claim 15 wherein:
the port transistor combination includes a port transistor of the one or more port transistors and a sensing transistor including a fourth drain, a fourth gate and a fourth source;
wherein:
the third drain of the port transistor and the fourth drain of the sensing transistor are connected; and
the third gate of the port transistor and the fourth gate of the sensing transistor are connected.

19. The chip package of claim 14 wherein the first chip base and the third drain are biased to a first voltage.

20. The chip package of claim 19 wherein the second chip base and the first drain are biased to a second voltage.

21. The chip package of claim 20 wherein the third chip base and the second source are biased to a third voltage.

22. The chip package of claim 21 wherein the controller is bonded to the third chip base through an electrically conductive adhesive.

23. The chip package of claim 21 wherein each port transistor of the one or more port transistors is a first vertically double-diffused metal-oxide-semiconductor field-effect transistor.

24. The chip package of claim 23 wherein the high-side transistor is a second vertically double-diffused metal-oxide-semiconductor field-effect transistor.

25. The chip package of claim 24 wherein the low-side transistor is a laterally double-diffused metal-oxide-semiconductor field-effect transistor.

26. The chip package of claim 14 wherein each port transistor of the one or more port transistors corresponds to a USB output port of the one or more USB output ports, the USB output port being configured to be connected to a load.

27. A chip package of a charging controller chip for a USB charger, the chip package comprising:
a high-side transistor including a first drain, a first gate and a first source;
a low-side transistor including a second drain, a second gate and a second source, the low-side transistor being connected to the high-side transistor;
one or more port transistors corresponding to one or more USB output ports respectively, each port transistor of the one or more port transistors including a third drain, a third gate and a third source;
a controller coupled to the high-side transistor, the low-side transistor, and the one or more port transistors;
a first chip base;
a second chip base electrically insulated from the first chip base; and
a third chip base electrically insulated from the first chip base and electrically insulated from the second chip base;
wherein:
the one or more port transistors and the controller are located on the first chip base;
the high-side transistor is located on the second chip base; and
the low-side transistor is located on the third chip base.

28. The chip package of claim 27 wherein:
the high-side transistor is a part of a high-side transistor combination that is located on the second chip base;
the low-side transistor is a part of a low-side transistor combination that is located on the third chip base; and
each port transistor of the one or more port transistors is a part of a port transistor combination that is located on the first chip base.

29. The chip package of claim 28 wherein:
the high-side transistor combination includes the high-side transistor and a sensing transistor including a fourth drain, a fourth gate and a fourth source;
wherein:
the first drain of the high-side transistor and the fourth drain of the sensing transistor are connected; and
the first gate of the high-side transistor and the fourth gate of the sensing transistor are connected.

30. The chip package of claim 28 wherein:
the low-side transistor combination includes the low-side transistor and a sensing transistor including a fourth drain, a fourth gate and a fourth source;
wherein:
the second drain of the low-side transistor and the fourth drain of the sensing transistor are connected; and
the second gate of the low-side transistor and the fourth gate of the sensing transistor are connected.

31. The chip package of claim 28 wherein:
the port transistor combination includes a port transistor of the one or more port transistors and a sensing transistor including a fourth drain, a fourth gate and a fourth source;
wherein:
the third drain of the port transistor and the fourth drain of the sensing transistor are connected; and
the third gate of the port transistor and the fourth gate of the sensing transistor are connected.

32. The chip package of claim 27 wherein the first chip base and the second source are biased to a first voltage.

33. The chip package of claim 32 wherein the controller is bonded to the first chip base through an electrically conductive adhesive.

34. The chip package of claim 32 wherein the second chip base and the first drain are biased to a second voltage.

35. The chip package of claim 34 wherein the third chip base, the first source and the second drain are biased to a third voltage.

36. The chip package of claim 35 wherein each port transistor of the one or more port transistors is a laterally double-diffused metal-oxide-semiconductor field-effect transistor.

37. The chip package of claim 36 wherein the high-side transistor is a first vertically double-diffused metal-oxide-semiconductor field-effect transistor.

38. The chip package of claim 37 wherein the low-side transistor is a second vertically double-diffused metal-oxide-semiconductor field-effect transistor.

39. The chip package of claim 27 wherein the first chip base and the third drain are biased to a first voltage.

40. The chip package of claim 39 wherein the controller is bonded to the first chip base through an electrically insulative adhesive.

41. The chip package of claim 39 wherein the second chip base and the first drain are biased to a second voltage.

42. The chip package of claim 41 wherein the third chip base, the first source and the second drain are biased to a third voltage.

43. The chip package of claim 42 wherein each port transistor of the one or more port transistors is a first vertically double-diffused metal-oxide-semiconductor field-effect transistor.

44. The chip package of claim 43 wherein the high-side transistor is a second vertically double-diffused metal-oxide-semiconductor field-effect transistor.

45. The chip package of claim 44 wherein the low-side transistor is a third vertically double-diffused metal-oxide-semiconductor field-effect transistor.

46. The chip package of claim 27 wherein each port transistor of the one or more port transistors corresponds to a USB output port of the one or more USB output ports, the USB output port being configured to be connected to a load.
